SEQUENCE LISTING (6 sequences)

SEQ ID NO: 1 - DNA, 29 bp, synthetic construct
  misc_feature 1..29: note = P5 primer
  source 1..29: mol_type = other DNA
  modified_base 23: mod_base = OTHER; note = n is deoxyuridine
aatgatacggcgaccaccgaganctacac

SEQ ID NO: 2 - DNA, 24 bp, synthetic construct
  misc_feature 1..24: note = Synthetic oligonucleotide
  source 1..24: mol_type = other DNA
caagcagaagacggcatacgagat

SEQ ID NO: 3 - DNA, 20 bp, synthetic construct
  misc_feature 1..20: note = Synthetic oligonucleotide
  source 1..20: mol_type = other DNA
aatgatacggcgaccaccga

SEQ ID NO: 4 - DNA, 21 bp, synthetic construct
  misc_feature 1..21: note = Synthetic oligonucleotide
  source 1..21: mol_type = other DNA
caagcagaagacggcatacga

SEQ ID NO: 5 - DNA, 29 bp, synthetic construct
  misc_feature 1..29: note = Synthetic oligonucleotide
  source 1..29: mol_type = other DNA
  modified_base 23: mod_base = OTHER; note = n is 5 prime-vinyl thymidine
aatgatacggcgaccaccgaganctacac

SEQ ID NO: 6 - DNA, 24 bp, synthetic construct
  misc_feature 1..24: note = P17 primer
  source 1..24: mol_type = other DNA
caagcagaagacggcatacgagat

(19) United States
(12) Patent Application Publication
(10) Pub. No.: US 2025/0010291 A1
(43) Pub. Date: Jan. 9, 2025

(54) PHOTORESIST PATTERNING IN MULTI-DEPTH NANOWELLS

(71) Applicant: Illumina, Inc., San Diego, CA (US)

(72) Inventors: Daniel Wright, San Diego, CA (US); Alexandra Szemjonov, Cambridge (GB); Wayne N. George, London (GB); Francesca Patel-Burrows, Cambridge (GB)

(21) Appl. No.: 18/753,229

(22) Filed: Jun. 25, 2024

Related U.S. Application Data
(60) Provisional application No. 63/510,819, filed on Jun. 28, 2023.

(51) Int. Cl. B01L 3/00

(52) U.S. Cl. CPC B01L 3/502715; B01L 3/502707; B01L 2300/0893; B01L 2300/0896

(57) ABSTRACT

Embodiments of the present disclosure relate to patterned substrates with functionalized surface such as flow cells, as well as methods of fabricating the patterned substrate. In particular, patterned substrates of the present disclosure may be prepared using two or more imprint resin layers, one of which acts as a photomask for the photoresist during substrate patterning, without the need of any metallic photomask. Embodiments of the patterned substrate may be used for simultaneous paired-end sequencing methods.

### CROSS-REFERENCE TO RELATED APPLICATION

This application claims the benefit of priority to U.S. Provisional Application No. 63/510,819, filed Jun. 28, 2023, the content of which is incorporated by reference in its entirety.

### REFERENCE TO SEQUENCE LISTING

The present application is being filed along with a Sequence Listing in electronic format. The Sequence Listing is provided as an electronic file entitled Sequence_Listing_ILLINC.788A.xml, created Jun. 7, 2024, which is 9.6 KB in size. The information in the electronic format of the Sequence Listing is incorporated herein by reference in its entirety.

### BACKGROUND

### Field

The present application relates to the fields of nanopatterning processes and substrates comprising microscale or nanoscale patterned surfaces.

### Description of the Related Art

Flow cells are devices that allow fluid flow through channels or wells within a substrate. Patterned flow cells that are useful in nucleic acid analysis methods include discrete wells having an active surface within inert interstitial regions. Flow cells fabricated through nanoimprint lithography (NIL) consist of a patterned crosslinked resin material on a glass substrate. Patterning is achieved by depositing a NIL resin containing polymerizable multifunctional monomers onto a glass substrate to create a thin film. A working stamp (WS) is pressed onto the resin surface and the NIL resin material deforms to fill the WS pattern. While the WS is still in contact with the surface, polymerization of the resin is initiated by exposure to light or heat, and the resin is cured. After the resin is sufficiently crosslinked such that it is no longer able to flow, the working stamp is peeled away from the surface, leaving behind an imprinted resin surface. The resulting nanostructured surface is then functionalized via multiple chemistry steps (e.g., salinization, hydrogel deposition, DNA oligo grafting) to support sequencing. In some approaches involving use of a photoresist, a metallic photomask is used so that the photoresist can be selectively patterned.

To ensure that DNA sequencing is spatially restricted into nanowells pre-defined by the working stamp pattern, the nanopatterned surfaces can be polished prior to the grafting of the DNA oligos.

Some available platforms for sequencing nucleic acids utilize a sequencing-by-synthesis approach (SBS). With this approach, nascent strands are synthesized, and the incorporation of labeled nucleotides to the growing strands are detected optically and/or electronically. Because template strands direct synthesis of the nascent strands, the sequence of the template DNAs may be determined from the sequential incorporated nucleotides that were added to the growing strand during SBS. In some examples, paired-end sequencing may be used, where forward strands are sequenced (read 1) and removed, and then reverse strands are constructed and sequenced (read 2). Simultaneous paired-end reading (SPEAR) methods have been reported in U.S. Publication No. 2021/0024991 which is incorporated by reference in its entirety. The SPEAR method can simultaneously sequence the forward (read 1) and reverse (read 2) DNA strands, thus reducing sequencing time in half. The spatial separation of read 1 and read 2 pads is generally required in complicated multiple nanopatterning steps involving several layers of materials, some of which act as temporary sacrificial masks. Such a nanopatterning process may include one or more etch steps, for example to prepare the surface of the NIL resin for addition of a photoresist or to remove an aluminum layer prior to addition of a hydrogel layer.

As such, there remains a demand to develop new cost-effective processes to simplify the substrate patterning processes. Provided herein are new process of manufacturing patterned substrate.

### SUMMARY

One aspect of the present disclosure relates to a patterned substrate, comprising:
a base support; and
an imprint layer comprising
   a first resin layer positioned over the base support, the first resin layer configured to allow passage of light;
   a second resin layer positioned over the first resin layer, the second resin layer configured as a photomask for blocking passage of light;
   a plurality of multi-level depressions, each multi-level depression comprising a deep well having a first inner well surface and a first surrounding surface, and a shallow well having a second inner well surface and a second surrounding surface, wherein the deep well and the shallow well are defined by a step portion, each of the first inner well surface and the second inner well surface is parallel to the base support, the first inner well surface resides within the first resin layer, and the second inner well surface resides within the second resin layer.

Another aspect of the present disclosure relates to a patterned substrate, comprising:
a base support; and
an imprint layer comprising
   a first resin layer positioned over the base support, the first resin layer configured to allow passage of light;
   a second resin layer positioned over the first resin layer, the second resin layer configured as a photomask to block passage of light;
   a third resin layer positioned over the second resin layer, the third resin layer configured to allow passage of light;
   a plurality of multi-level depressions, each depression comprising a deep well having a first inner well surface and a first surrounding surface, and a shallow well having a second inner well surface and a second surrounding surface, wherein the deep well and the shallow well are defined by a step portion, each of the first inner well surface and the second inner well surface is parallel to the base support, the first surface resides within the first resin layer, and the second inner well surface resides within either the second resin layer or third resin layer.

Another aspect of the present disclosure relates to a method for functionalizing a surface of a patterned substrate, comprising:
depositing a first functionalized molecule on the patterned substrate of claim 1, wherein the first functionalized molecule covers a top surface of the second resin layer and the surfaces of at least a portion of the deep wells and the shallow wells of the plurality multi-level depressions;
introducing a photoresist into the multi-level depressions of the substrate;
exposing the substrate to light from a backside of the base support opposite to the imprint layer such that only the photoresist residing within the deep wells of the multi-level depressions are cured, and the photoresist residing within the shallow wells of the multi-level depressions remains unexposed to light and uncured; and
removing the uncured photoresist from the substrate.

Another aspect of the present disclosure relates to a method for functionalizing a surface of a patterned substrate, comprising:
depositing a first functionalized molecule on the patterned substrate in accordance with the present disclosure, wherein the first functionalized molecule covers a top surface of the third resin layer and the surfaces of at least a portion of the deep wells and the shallow wells of the plurality multi-level depressions;
introducing a photoresist into the multi-level depressions of the substrate;
exposing the substrate to light from a backside of the base support opposite to the imprint layer such that only the photoresist residing within the deep wells of the multi-level depressions are cured, and the photoresist residing within the shallow wells of the multi-level depressions remains unexposed to light and uncured; and
removing the uncured photoresist from the substrate.

Another aspect of the present disclosure relates to a method for functionalizing a surface of a patterned substrate comprising a plurality of multi-level depressions, the method comprising:
introducing a photoresist into the multi-level depressions of the patterned substrate in accordance with the present disclosure;
exposing the substrate to light from a backside of the base support opposite to the imprint layer such that only the photoresist residing within the deep wells of the multi-level depressions is cured, and the photoresist residing within the shallow wells of the multi-level depressions remains unexposed to light and uncured;
removing the uncured photoresist from the substrate;
etching the imprint layer to remove the second resin layer and to form a third inner well surface in each of the shallow wells, wherein the third inner well surface resides within the first resin layer, and the third inner well surface is parallel to the base support;
depositing a first functionalized molecule on the first resin layer to cover at least a portion of the third inner well surfaces and the cured photoresist;
removing the cured photoresist from the substrate, thereby exposing the first inner well surfaces; and
depositing a second functionalized molecule on the first inner well surfaces.

Another aspect of the present disclosure relates to a method for functionalizing a surface of a patterned substrate comprising a plurality of multi-level depressions, comprising:
introducing a positive photoresist into the multi-level depressions of the patterned substrate in accordance with the present disclosure;
exposing the substrate to light from a backside of the base support opposite to the imprint layer such that only the photoresist residing within the deep wells of the multi-level depressions is exposed to light, and the photoresist residing within the shallow wells of the multi-level depressions remains unexposed to light;
removing light exposed photoresist from the substrate;
depositing a functionalized molecule on the imprint layer of the substrate to cover at least a portion of the first inner well surfaces;
removing the second resin layer and remaining unexposed positive photoresist by etching.

### BRIEF DESCRIPTION OF THE DRAWINGS

FIGS. 1 and 2 illustrate substrate patterning workflows involving a light-absorbent, etchable resin to form a patterned substrate having two functionalized regions, where the first functionalized molecule is applied before the photoresist is cured.

FIGS. 3 and 4 illustrate substrate patterning workflows involving a light-absorbent, etchable resin to form a substrate having two functionalized regions, where the first functionalized molecule is applied after the photoresist is cured.

FIG. 5 illustrates a substrate patterning workflow including a positive tone photoresist.

FIG. 6A plots absorption as a function of wavelength of an organic acrylate resin mixed with 5 nm titanium oxide nanoparticles at different concentrations.

FIG. 6B plots absorbance as a function of wavelength of an organic acrylate resin mixed with 100 nm titanium oxide nanoparticles at different concentrations.

FIG. 6C is a scanning electron microscopy image of an imprintable organic acrylate resin mixed with titanium oxide nanoparticles.

FIG. 7A plots absorbance as a function of wavelength of organic acrylate resin mixed with bisoctrizole.

FIG. 7B is a scanning electron microscopy image of an imprintable organic acrylate resin mixed with bisoctrizole.

FIG. 8A plots absorbance as a function of wavelength of organic acrylate resin mixed with avobenzone.

FIG. 8B is a scanning electron microscopy image of an imprintable organic acrylate resin mixed with avobenzone.

FIG. 9 plots absorption as a function of wavelength of organic acrylate resin mixed with zinc acrylate.

### DETAILED DESCRIPTION

The present disclosure relates to the substrates and fabrication processes thereof. Described herein are processes of preparing patterned substrate suitable for a SPEAR application where a resin layer acts as a photomask. In particular, the substrates disclosed herein include flow cells which may be used for nucleic acid sequencing, in particular sequencing by synthesis (SBS). It may be desirable to use a resin layer as a photomask, as such layers can be easily removed, for example via etching.

The section headings used herein are for organizational purposes only and are not to be construed as limiting the subject matter described.

### Definitions

Unless defined otherwise, all technical and scientific terms used herein have the same meaning as is commonly understood by one of ordinary skill in the art. The use of the term “including” as well as other forms, such as “include,” “includes,” and “included,” is not limiting. The use of the term “having” as well as other forms, such as “have,” “has,” and “had,” is not limiting. As used in this specification, whether in a transitional phrase or in the body of the claim, the terms “comprise(s)” and “comprising” are to be interpreted as having an open-ended meaning. That is, the above terms are to be interpreted synonymously with the phrases “having at least” or “including at least.” For example, when used in the context of a process, the term “comprising” means that the process includes at least the recited steps but may include additional steps. When used in the context of a compound, composition, or device, the term “comprising” means that the compound, composition, or device includes at least the recited features or components, but may also include additional features or components.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount.

The term “and/or” as used herein has its broadest least limiting meaning, which is the disclosure includes A alone, B alone, both A and B together, or A or B alternatively, but does not require both A and B or require one of A or one of B. As used herein, the phrase “at least one of” A, B, “and” C should be construed to mean a logical A or B or C, using a non-exclusive logical “or.”

The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

As used herein, common abbreviations are defined as follows:
dATP Deoxyadenosine triphosphate
dCTP Deoxycytidine triphosphate
dGTP Deoxyguanosine triphosphate
dTTP Deoxythymidine triphosphate
PAZAM Poly(N-(5-azidoacetamidylpentyl) acrylamide-co-acrylamide) of any acrylamide to azapa ratio
SBS Sequencing-by-synthesis

As used herein, the term “attached” refers to the state of two things being joined, fastened, adhered, connected, or bound to each other. For example, an analyte, such as a nucleic acid, can be attached to a material, such as a gel or solid support, by a covalent or non-covalent bond. A covalent bond is characterized by the sharing of pairs of electrons between atoms. A non-covalent bond is a chemical bond that does not involve the sharing of pairs of electrons and can include, for example, hydrogen bonds, ionic bonds, van der Waals forces, hydrophilic interactions, and hydrophobic interactions.

As used herein, the term “array” refers to a population of different probes (e.g., probe molecules) that are attached to one or more substrates such that the different probes can be differentiated from each other according to relative location. An array can include different probes that are each located at a different addressable location on a substrate. Alternatively or additionally, an array can include separate substrates each bearing a different probe, wherein the different probes can be identified according to the locations of the substrates on a surface to which the substrates are attached or according to the locations of the substrates in a liquid. Further examples of arrays that can be used in the invention include, without limitation, those described in U.S. Pat. Nos. 5,429,807; 5,436,327; 5,561,071; 5,583,211; 5,658,734; 5,837,858; 5,874,219; 5,919,523; 6,136,269; 6,287,768; 6,287,776; 6,288,220; 6,297,006; 6,291,193; 6,346,413; 6,416,949; 6,482,591; 6,514,751; and 6,610,482; WO 93/17126; WO 95/11995; WO 95/35505; EP 742 287; and EP 799 897.

As used herein, the term “covalently attached” or “covalently bonded” refers to the forming of a chemical bonding that is characterized by the sharing of pairs of electrons between atoms. For example, a covalently attached hydrogel refers to a hydrogel that forms chemical bonds with a functionalized surface of a substrate, as compared to attachment to the surface via other means, for example, adhesion or electrostatic interaction. It will be appreciated that polymers that are attached covalently to a surface can also be bonded via means in addition to covalent attachment.

As used herein, the term “non-covalent interactions” differs from a covalent bond in that it does not involve the sharing of electrons, but rather involves more dispersed variations of electromagnetic interactions between molecules or within a molecule. Non-covalent interactions can be generally classified into four categories, electrostatic, π-effects, van der Waals forces, and hydrophobic effects. Non-limiting examples of electrostatic interactions include ionic interactions, hydrogen bonding (a specific type of dipole-dipole interaction), halogen bonding, etc. Van der Walls forces are a subset of electrostatic interaction involving permanent or induced dipoles or multipoles. π-effects can be broken down into numerous categories, including (but not limited to) π-π interactions, cation-π and anion-π interactions, and polar-π interactions. In general, π-effects are associated with the interactions of molecules with the π-orbitals of a molecular system, such as benzene. The hydrophobic effect is the tendency of nonpolar substances to aggregate in aqueous solution and exclude water molecules. Non-covalent interactions can be both intermolecular and intramolecular. Non-covalent interactions can be both intermolecular and intramolecular.

As used herein, the term “coat,” when used as a verb, is intended to mean providing a layer or covering on a surface. At least a portion of the surface can be provided with a layer or cover. In some cases, the entire surface can be provided with a layer or cover. In alternative cases only a portion of the surface will be provided with a layer or covering. The term “coat,” when used to describe the relationship between a surface and a material, is intended to mean that the material is present as a layer or cover on the surface. The material can seal the surface, for example, preventing contact of liquid or gas with the surface. However, the material need not form a seal. For example, the material can be porous to liquid, gas, or one or more components carried in a liquid or gas. Exemplary materials that can coat a surface include, but are not limited to, a gel, polymer, organic polymer, liquid, metal, a second surface, plastic, silica, or gas.

As used herein the term “analyte” is intended to include any of a variety of analytes that are to be detected, characterized, modified, synthesized, or the like. Exemplary analytes include, but are not limited to, nucleic acids (e.g., DNA, RNA, or analogs thereof), proteins, polysaccharides, cells, nuclei, cellular organelles, antibodies, epitopes, receptors, ligands, enzymes (e g kinases, phosphatases, or polymerases), peptides, small molecule drug candidates, or the like. An array can include multiple different species from a library of analytes. For example, the species can be different antibodies from an antibody library, nucleic acids having different sequences from a library of nucleic acids, proteins having different structure and/or function from a library of proteins, drug candidates from a combinatorial library of small molecules, etc.

As used herein, directional language, for example “over,” “above,” “below,” “top,” and “bottom,” are meant to indicate directions with respect to the substrates as depicted in the figures. For instance, generally the base layer/base support is regarded herein as being at the bottom of the substrate, with other layers being layered over and/or above the base layer. Directional language herein is meant only to be descriptive with reference to the figures and is not intended to be limiting. For example, some embodiments may be implemented such that the base layer is the top surface and that the other layers, for example the imprint layer, are below the base layer.

As used herein the term “contour” is intended to mean a localized variation in the shape of a surface. Exemplary contours include, but are not limited to, wells, pits, channels, posts, pillars, and ridges. Contours can occur as any of a variety of depressions in a surface or projections from a surface. All or part of a contour can serve as a feature in an array. For example, a part of a contour that occurs in a particular plane of a solid support can serve as a feature in that particular plane. In some embodiments, contours are provided in a regular or repeating pattern on a surface.

As used herein, the term “depression” refers to a discrete concave contour in a patterned support having a surface opening that is completely surrounded by interstitial region(s) of the patterned support surface. Depressions can have any of a variety of shapes at their opening in a surface including, as examples, round, elliptical, square, polygonal, star shaped (with any number of vertices), etc. The cross-section of a depression taken orthogonally with the surface can be curved, square, polygonal, hyperbolic, conical, angular, stepped, etc. For example, the wells described herein are considered as depressions.

Where a material is “within” a contour, it is located in the space of the contour. For example, for a depression such as a well, the material is inside the well, and for a projection such as a pillar or post, the material covers the contour that extends above the plane of the surface.

As used herein, the term “different,” when used in reference to nucleic acids, means that the nucleic acids have nucleotide sequences that are not the same as each other. Two or more nucleic acids can have nucleotide sequences that are different along their entire length. Alternatively, two or more nucleic acids can have nucleotide sequences that are different along a substantial portion of their length. For example, two or more nucleic acids can have target nucleotide sequence portions that are different for the two or more molecules while also having a universal sequence portion that is the same on the two or more molecules. The term can be similarly applied to proteins which are distinguishable as different from each other based on amino acid sequence differences.

As used herein, the term “each,” when used in reference to a collection of items, is intended to identify an individual item in the collection but does not necessarily refer to every item in the collection. Exceptions can occur if explicit disclosure or context clearly dictates otherwise.

As used herein, the term “feature” means a location in an array that is configured to attach a particular analyte. For example, a feature can be all or part of a contour on a surface. A feature can contain only a single analyte, or it can contain a population of several analytes, optionally the several analytes can be the same species. In some embodiments, features are present on a solid support prior to attaching an analyte. In other embodiments the feature is created by attachment of an analyte to the solid support.

As used herein, the term “flow cell” is intended to mean a vessel having a chamber where a reaction can be carried out, an inlet for delivering reagents to the chamber and an outlet for removing reagents from the chamber. In some embodiments, the chamber is configured for detection of the reaction that occurs in the chamber (e.g., on a surface that is in fluid contact with the chamber). For example, the chamber can include one or more transparent surfaces allowing optical detection of arrays, optically labeled molecules, or the like in the chamber. Exemplary flow cells include, but are not limited to, those used in a nucleic acid sequencing apparatus such as flow cells for the Genome Analyzer®, MiSeq®, NextSeq® or HiSeq® platforms commercialized by Illumina, Inc. (San Diego, CA); or for the SOLiD™ or Ion Torrent™ sequencing platform commercialized by Life Technologies (Carlsbad, CA). Exemplary flow cells and methods for their manufacture and use are also described, for example, in WO 2014/142841 A1; U.S. Pat. App. Pub. No. 2010/0111768 A1 and U.S. Pat. No. 8,951,781, each of which is incorporated herein by reference.

As used herein, the term “hydrogel” or “gel material” is intended to mean a semi-rigid material that is permeable to liquids and gases. Typically, a hydrogel material can swell when liquid is taken up and can contract when liquid is removed, e.g., by drying. Exemplary hydrogels include, but are not limited to, those having a colloidal structure, such as agarose; polymer mesh structure, such as gelatin; or cross-linked polymer structure, such as polyacrylamide, silane free acrylamide (see, for example, US Pat. App. Pub. No. 2011/0059865 A1), PAZAM (see, for example, U.S. Pat. No. 9,012,022, which is incorporated herein by reference), and polymers described in U.S. Patent Pub. Nos. 2015/0005447 and 2016/0122816, all of which are incorporated by reference in their entireties. Particularly useful gel material will conform to the shape of a well or other contours where it resides. Some useful hydrogel materials can both (a) conform to the shape of the well or other contours where it resides and (b) have a volume that does not substantially exceed the volume of the well or contours where it resides.

As used herein, the term “interstitial region” refers to an area in a substrate or on a surface that separates other areas of the substrate or surface. The interstitial region does not allow for the binding of library DNA. For example, an interstitial region can separate one library DNA binding region from another library DNA binding region. The two regions that are separated from each other can be discrete, lacking contact with each other. In some embodiments the interstitial region is continuous whereas the contours or features are discrete, for example, as is the case for an array of wells in an otherwise continuous surface. The separation provided by an interstitial region can be partial or full separation. Interstitial regions may have a surface material that differs from the surface material of the contours or features on the surface. For example, contours of an array can have an amount or concentration of gel material or analytes that exceeds the amount or concentration present at the interstitial regions.

As used herein, the terms “nucleic acid” and “nucleotide” are intended to be consistent with their use in the art and to include naturally occurring species or functional analogs thereof. Particularly useful functional analogs of nucleic acids are capable of hybridizing to a nucleic acid in a sequence specific fashion or capable of being used as a template for replication of a particular nucleotide sequence. Naturally occurring nucleic acids generally have a backbone containing phosphodiester bonds. An analog structure can have an alternate backbone linkage including any of a variety of those known in the art. Naturally occurring nucleic acids generally have a deoxyribose sugar (e.g., found in deoxyribonucleic acid (DNA)) or a ribose sugar (e.g., found in ribonucleic acid (RNA)). A nucleic acid can contain nucleotides having any of a variety of analogs of these sugar moieties that are known in the art. A nucleic acid can include native or non-native nucleotides. In this regard, a native deoxyribonucleic acid can have one or more bases selected from the group consisting of adenine, thymine, cytosine or guanine and a ribonucleic acid can have one or more bases selected from the group consisting of uracil, adenine, cytosine, or guanine. Useful non-native bases that can be included in a nucleic acid or nucleotide are known in the art. The terms “probe” or “target,” when used in reference to a nucleic acid, are intended as semantic identifiers for the nucleic acid in the context of a method or composition set forth herein and does not necessarily limit the structure or function of the nucleic acid beyond what is otherwise explicitly indicated. The terms “probe” and “target” can be similarly applied to other analytes such as proteins, small molecules, cells, or the like.

As used herein, the term “orthogonal” in the context of chemical reaction, it refers to the situation when there are two pairs of substances and each substance can interact with their respective partner, but does not interact with either substance of the other pair. In the context of the first and the second functionalized molecules, it refers to that the first functional groups of the first functionalized molecule will selectively react with certain chemical entities, while the second functional groups of the second functionalized molecule will have little or no reactivity towards the same chemical entities that are reactive to the first functional groups of the first functionalized molecule.

As used herein, the term “surface” is intended to mean an external part or external layer of a solid support or gel material. The surface can be in contact with another material such as a gas, liquid, gel, polymer, organic polymer, second surface of a similar or different material, metal, or coat. The surface, or regions thereof, can be substantially flat or planar. The surface can have surface contours such as wells, pits, channels, ridges, raised regions, pegs, posts or the like.

As used herein, the “solid support” or “substrate” may be used interchangeably, and both refer to a rigid substrate that is insoluble in aqueous liquid. The substrate can be non-porous or porous. The solid support can optionally be capable of taking up a liquid (e.g., due to porosity) but will typically be sufficiently rigid that the substrate does not swell substantially when taking up the liquid and does not contract substantially when the liquid is removed by drying. A nonporous solid support is generally impermeable to liquids or gases. Exemplary solid supports include, but are not limited to, glass and modified or functionalized glass, plastics (e.g., acrylics, polystyrene and copolymers of styrene and other materials, polypropylene, polyethylene, polybutylene, polyurethanes, Teflon™, cyclic olefins, polyimides, etc.), nylon, ceramics, resins, Zeonor, silica or silica-based materials including silicon and modified silicon, carbon, metals, inorganic glasses, optical fiber bundles, and polymers. A particularly useful material is glass. Other suitable substrate materials may include polymeric materials, plastics, silicon, quartz (fused silica), borofloat glass, silica, silica-based materials, carbon, metals including gold, an optical fiber or optical fiber bundles, sapphire, or plastic materials such as COCs and epoxies. The particular material can be selected based on properties desired for a particular use. For example, materials that are transparent to a desired wavelength of radiation are useful for analytical techniques that will utilize radiation of the desired wavelength, such as one or more of the techniques set forth herein. Conversely, it may be desirable to select a material that does not pass radiation of a certain wavelength (e.g., being opaque, absorptive, or reflective). This can be useful for formation of a mask to be used during manufacture of the structured substrate; or to be used for a chemical reaction or analytical detection carried out using the structured substrate. Other properties of a material that can be exploited are inertness or reactivity to certain reagents used in a downstream process; or ease of manipulation or low cost during a manufacturing process manufacture. Further examples of materials that can be used in the structured substrates or methods of the present disclosure are described in US Pat. App. Pub. No. 2012/0316086 A1 and 2013/0116153, each of which is incorporated herein by reference.

As used herein, the term “well” refers to a discrete contour in a solid support having a surface opening that is completely surrounded by interstitial region(s) of the surface. Wells can have any of a variety of shapes at their opening in a surface including but not limited to round, elliptical, square, polygonal, star shaped (with any number of vertices), etc. The cross section of a well taken orthogonally with the surface can be curved, square, polygonal, hyperbolic, conical, angular, etc. In some embodiments, the well is a microwell or a nanowell.

As used herein, the term “clustering oligonucleotide” or “clustering primer” refers to nucleotide sequence immobilized on the surface of the solid support used for amplifying the template polynucleotides to create identical copies of the same templates (i.e., clusters). Examples of clustering oligonucleotide may include but not limited to P5 primer, P7 primer, P15 primer, P17 primer as described herein. In some embodiments, the “clustering primer” is also referred to as a “surface primer.”

The P5 and P7 primers are used on the surface of commercial flow cells sold by Illumina Inc. The P5 and/or P7 primers, can be used for sequencing on HiSeq™, HiSeqX™, MiSeq™ MiSeqDX™, MiniSeq™, NextSeq™, NextSeqDX™, NovaSeq™, Genome Analyzer™, ISEQ™, and other instrument platforms. These primers are also referred to as the “clustering primers” or “clustering oligonucleotides.” The primer sequences are described in U.S. Pat. Pub. No. 2011/0059865 A1, which is incorporated herein by reference. The P5 and P7 primer sequences comprise the following:

Paired end set:
P5: paired end 5′→3′
SEQ ID NO. 1: AATGATACGGCGACCACCGAGAUCTACAC
P7: paired end 5′→3′
SEQ ID NO. 2: CAAGCAGAAGACGGCATACGAGAT
Single read set:
P5: single read 5′→3′
SEQ ID NO. 3: AATGATACGGCGACCACCGA
P7: single read 5′→3′
SEQ ID NO. 4: CAAGCAGAAGACGGCATACGA

In some embodiments, the P5 and P7 primers may comprise a linker or spacer at the 5′ end. Such linker or spacer may be included in order to permit cleavage, or to confer some other desirable property, for example to enable covalent attachment to a polymer or a solid support, or to act as spacers to position the site of cleavage an optimal distance from the solid support. In certain cases, 10-50 spacer nucleotides may be positioned between the point of attachment of the P5 or P7 primers to a polymer or a solid support. In some embodiments polyT spacers are used, although other nucleotides and combinations thereof can also be used. TET is a dye labeled oligonucleotide having complementary sequence to the P5/P7 primers. TET can be hybridized to the P5/P7 primers on a surface; the excess TET can be washed away, and the attached dye concentration can be measured by fluorescence detection using a scanning instrument such as a Typhoon Scanner (General Electric). In addition to the P5/P7 primers, other non-limiting examples of the sequencing primer sequences such as P15/P17 primers have also been disclosed in U.S. Publication No. 2019/0352327. These additional clustering primers comprise the following:

P15: 5′→3′
SEQ ID NO. 5: AATGATACGGCGACCACCGAGAT*CTACAC

where T* refers to modified T containing an allyl moiety (5′-vinyl thymidine).

P17: 5′→3′
SEQ ID NO. 6: YYYCAAGCAGAAGACGGCATACGAGAT

where Y is a diol linker subject to chemical cleavage, for example, by oxidation with a reagent such as periodate, as disclosed in U.S. Publication No. 2012/0309634, which is incorporated by preference in its entirety.

As used herein, the term “amino” refers to a “—NR_{A}R_{B}” group in which R_{A} and R_{B} are each independently selected from hydrogen, C₁₋₆ alkyl, C₂₋₆ alkenyl, C₂₋₆ alkynyl, C₃₋₇ carbocyclyl, C₆₋₁₀ aryl, 5-10 membered heteroaryl, and 5-10 membered heterocyclyl, as defined herein. A non-limiting example includes free amino (i.e., —NH₂).

As used herein, the term “azido” refers to a —N₃ group.

As used herein, the term “carboxyl” refers to a —C(═O)OH group.

As used herein, the term “thiol” refers to a —SH group.

As used herein, “vinyl” refers to a —CH═CH₂ group.

As used herein, the term “epoxy” as used herein refers to or

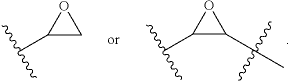

As used herein, the term “glycidyl” as used herein refers to

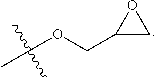 [SMILES: *OCC1CO1]

The embodiments set forth herein and recited in the claims can be understood in view of the above definitions.

### Patterned Substrate

One aspect of the present disclosure relates to a patterned substrate, comprising:
a base support; and
an imprint layer comprising
   a first resin layer positioned over the base support, the first resin layer configured to allow passage of light;
   a second resin layer positioned over the first resin layer, the second resin layer configured as a photomask for blocking passage of light;
   a plurality of multi-level depressions, each multi-level depression comprising a deep well having a first inner well surface and a first surrounding surface, and a shallow well having a second inner well surface and a second surrounding surface, wherein the deep well and the shallow well are defined by a step portion, each of the first inner well surface and the second inner well surface is parallel to the base support, the first inner well surface resides within the first resin layer, and the second inner well surface resides within the second resin layer.

Another aspect of the present disclosure relates to a patterned substrate, comprising:
a base support; and
an imprint layer comprising
   a first resin layer positioned over the base support, the first resin layer configured to allow passage of light;
   a second resin layer positioned over the first resin layer, the second resin layer configured as a photomask to block passage of light;
   a third resin layer positioned over the second resin layer, the third resin layer configured to allow passage of light;
   a plurality of multi-level depressions, each depression comprising a deep well having a first inner well surface and a first surrounding surface, and a shallow well having a second inner well surface and a second surrounding surface, wherein the deep well and the shallow well are defined by a step portion, each of the first inner well surface and the second inner well surface is parallel to the base support, the first surface resides within the first resin layer, and the second inner well surface resides within either the second resin layer or third resin layer.

In some embodiments of the patterned substrate including a third resin layer, the second inner well surface resides within the second resin layer. In some further embodiments, the first resin layer and third resin layer comprise the same material. For example, in such embodiments, the first resin layer and third resin layers comprise the same formulation of resin.

In some embodiments of the patterned substrate, the patterned substrate is capable of exposing a photoresist positioned within the deep well of the depression over the first inner well surface to a light passing through the base support and the first resin layer. In some embodiments of the patterned substrate, the first resin layer is configured to allow passage of UV light, and wherein the second resin is configured as a photomask for UV light. In some embodiments of the patterned substrate, the patterned substrate does not include a metallic photomask. In some embodiments of the patterned substrate, the second resin layer is dry etchable. In some embodiments of the patterned substrate, the second resin layer is wet etchable. In further embodiments, the second resin layer is both wet etchable and dry etchable. In some embodiments of the patterned substrate, the first resin layer is not wet etchable. In some embodiments of the patterned substrate, the first resin layer is dry etchable. In some embodiments of the patterned substrate, the second resin layer comprises an epoxy resin and one or more light-absorbing agents. In further embodiments, the epoxy resin may include at least one of any suitable epoxy resin material, for example those disclosed herein: 3,4-epoxycyclohexylmethyl 3,4-epoxycyclohexanecarboxylate (ECHC), trimethylolpropane triglycidyl ether (TTE), BIS(4-methylphenyl)iodonium hexafluorophosphate (IPF), tris (4-((4-acetylphenyl)thio)phenyl)-sulfonium tetrakis(perfluoro-phenyl) borate (PAG290), or diphenyl (2,4,6-trimethylbenzoyl)phosphine oxide (DPBAPO). In some embodiments, the second resin layer comprises an acrylate resin and one or more light-absorbing agents. In further embodiments, the acrylate resin may include at least one of any suitable acrylate resin material, for example those disclosed herein: pentaerythritol triacrylate (PE3A) or diphenyl (2,4,6-trimethylbenzoyl)phosphine oxide (DPBAPO). In some embodiments, the second resin layer comprises at least one leveling agent. In further embodiments, the leveling agent may include BYK-350 (BYK-Chemie GmbH), BYK-394 (BYK-Chemie GmbH), BYK-354 (BYK-Chemie GmbH), BYK-392 (BYK-Chemie GmbH), BYK-352 (BYK-Chemie GmbH), BYK-356 (BYK-Chemie GmbH), and BYK-359 (BYK-Chemie GmbH), and combinations thereof. In embodiments where the second resin includes one or more light-absorbing agents, the one or more light-absorbing agents may include one or more UV-absorbing agents. In some embodiments, the thickness of the second resin layer defined between the first resin layer and a top surface of the second resin layer is between about 20 nm and about 1 μm.

### Functionalized Molecules

In some embodiments of the patterned substrate described herein, a first functionalized molecule covers at least a portion of the first surface, and a second functionalized molecule covers at least a portion of the second surface. In some embodiments, the first functionalized molecule is a functionalized hydrogel or polymer comprising a plurality of first functional groups, the second functionalized molecule is a functionalized hydrogel or polymer comprising a plurality of second functional groups, and wherein the first functional groups are orthogonal to the second functional groups. In some embodiments, the functionalized molecule includes a functionalized hydrogel. In some embodiments, the functionalized molecule includes a functionalized polymer.

The functionalized hydrogel described herein may comprise two or more recurring monomer units in any order or configuration, and may be linear, cross-linked, or branched, or a combination thereof. In an example, the polymer may be a heteropolymer and the heteropolymer may include an acrylamide monomer, such as

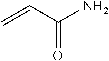

or a substituted analog thereof. The polymer or hydrogel may be coated on the surface either by covalent or non-covalent attachment.

In some embodiments, the hydrogel comprises the repeating units of:

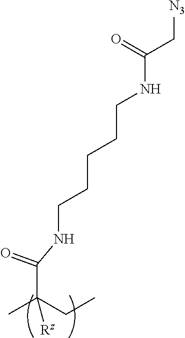

and optionally

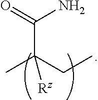

where each R^{z} is independently H or C₁-C₄ alkyl. In an example, a polymer used may include examples such as a poly(N-(5-azidoacetamidylpentyl)acrylamide-co-acrylamide), also known as PAZAM:

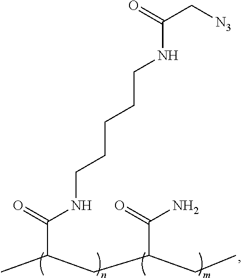

wherein n is an integer in the range of 1-20,000, and m is an integer in the range of 1-100,000. In some examples, the acrylamide monomer may include an azido acetamido pentyl acrylamide monomer:

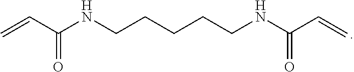

In some examples, the hydrogel may comprise repeating units of

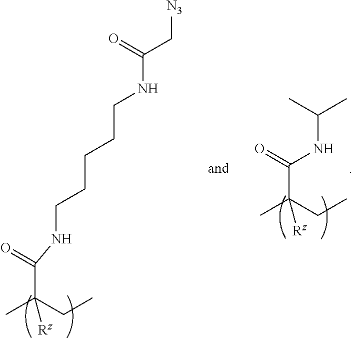

In further embodiments, the hydrogel may comprise the structure:

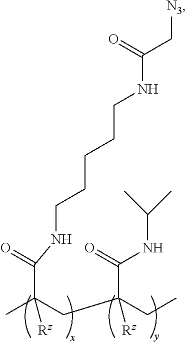

wherein x is an integer in the range of 1-20,000, and y is an integer in the range of 1-100,000, or

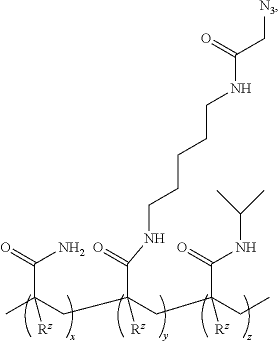

wherein y is an integer in the range of 1-20,000 and x and z are integers wherein the sum of x and z may be within a range of from 1 to 100,000, where each R^{z} is independently H or C₁₋₄ alkyl and a ratio of x:y may be from approximately 10:90 to approximately 1:99, or may be approximately 5:95, or a ratio of (x:y):z may be from approximately 85:15 to approximately 95:5, or may be approximately 90:10 (wherein a ratio of x:(y:z) may be from approximately 1:(99) to approximately 10:(90), or may be approximately 5:(95)), respectively.

In an example, the polymeric hydrogel includes an acrylamide copolymer, such as PAZAM. The molecular weight of PAZAM and other forms of the acrylamide copolymer may range from about 5 kDa to about 1500 kDa or from about 10 kDa to about 1000 kDa, or may be, in a specific example, about 312 kDa. In some examples, PAZAM and other forms of the acrylamide copolymer are linear polymers. In some other examples, PAZAM and other forms of the acrylamide copolymer are a lightly cross-linked polymers.

As still another example, the hydrogel may include a recurring unit of each of structure (III) and (IV):

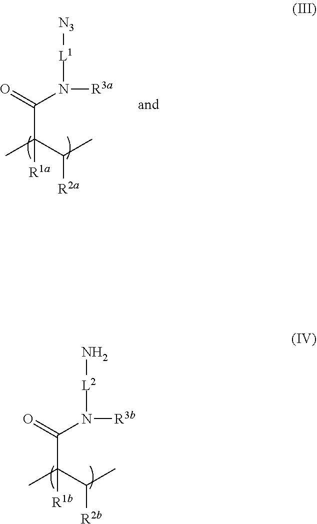

wherein each of R^{1a}, R^{2a}, R^{1b} and R^{2b} is independently selected from hydrogen, an optionally substituted alkyl or optionally substituted phenyl; each of R^{3a} and R^{3b} is independently selected from hydrogen, an optionally substituted alkyl, an optionally substituted phenyl, or an optionally substituted C₇-C₁₄ aralkyl; and each L¹ and L² is independently selected from an optionally substituted alkylene linker or an optionally substituted heteroalkylene linker.

In some embodiments of the patterned substrate described herein, at least a portion of the multi-level depressions are multi-level nanowells, each nanowell comprising a deep well and a shallow well.

In some embodiments of the patterned substrate described herein, the base support comprises a glass. In some embodiments of the patterned substrate described herein, the base support may be transparent. The base support may include any suitable material. The base support 102 may be optically transparent. The base support may be optically transparent to at least a wavelength capable of photocuring a photoresist. Examples of suitable materials for the base support include epoxy siloxane, glass and modified or functionalized glass, plastics (including acrylics, polystyrene and copolymers of styrene and other materials, polypropylene, polyethylene, polybutylene, polyurethanes, polytetrafluoroethylene (such as TEFLON® from Chemours), cyclic olefins/cyclo-olefin polymers (COP) (such as ZEONOR® from Zeon), polyimides, etc.), nylon, ceramics/ceramic oxides, silica, fused silica, or silica-based materials, aluminum silicate, silicon and modified silicon (e.g., boron doped p+ silicon), silicon nitride (Si₃N₄), silicon oxide (SiO₂), tantalum pentoxide (Ta₂O₅) or other tantalum oxide(s) (TaOx), hafnium oxide (HfO₂), carbon, metals, inorganic glasses, or the like. The base support 102 may also be a multi-layered structure. Some examples of the multi-layered structure include glass or silicon, with a coating layer of tantalum oxide or another ceramic oxide at the surface. Still other examples of the multi-layered structure may include a silicon-on-insulator (SOI) substrate.

### Imprint Layer

In some embodiments of the patterned substrate described herein, the imprint layer may include any suitable material in accordance with the present disclosure. The imprint layer may include a resin material. The resin material may be, for example, a nanoimprinting lithography (NIL) resin. In one aspect, the present disclosure provides materials as an imprint layer for preparing a surface of a substrate (e.g., a flow cell) that avoids an etch step. The imprint layer may also be referred to herein as the nanoimprint lithography (NIL) layer.

In some embodiments, the imprint layer may include a silsesquioxane. As used herein, the term “polyhedral oligomeric silsesquioxane” (“POSS,” commercially available from Hybrid plastics) refers to a chemical composition that is a hybrid intermediate (e.g., RSiO1.5) between that of silica (SiO2) and silicone (R2SiO). An example of POSS may be that described in Kehagias et al., Microelectronic Engineering 86 (2009), pp. 776-778, which is incorporated by reference in its entirety. In an example, the composition is an organosilicon compound with the chemical formula [RSiO3/2]n, where the R groups can be the same or different. Example R groups for POSS include epoxy, azide/azido, a thiol, a poly(ethylene glycol), a norbornene, a tetrazine, acrylates, and/or methacrylates, or further, for example, alkyl, aryl, alkoxy, and/or haloalkyl groups.

The imprint layer may include an epoxy material. Any suitable epoxy monomer or cross-linkable epoxy copolymer may be used as the epoxy material. The epoxy resin matrix includes at least one epoxy material. Any suitable epoxy monomer or cross-linkable epoxy copolymer may be used as the epoxy material. The epoxy material may be selected from an epoxy functionalized silsesquioxane (described further hereinbelow). For example,
trimethylolpropane triglycidyl ether:

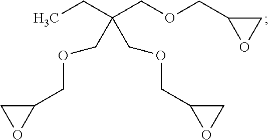 [SMILES: CCC(COCC1CO1)(COCC1CO1)COCC1CO1]

tetrakis(epoxycyclohexyl ethyl)tetramethyl cyclotetrasiloxane:

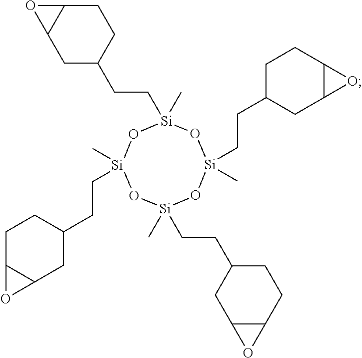 [SMILES: C[Si]1(CCC2CCC3OC3C2)O[Si](C)(CCC2CCC3OC3C2)O[Si](C)(CCC2CCC3OC3C2)O[Si](C)(CCC2CCC3OC3C2)O1]

a copolymer of (epoxycyclohexylethyl)methylsiloxane and dimethylsiloxane:

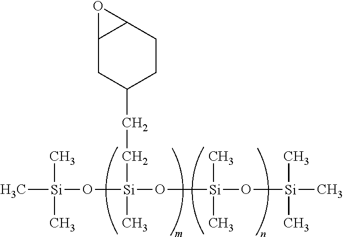

(wherein a ratio of m:n ranges from 8:92 to 10:90);
1,3-bis[2-(3,4-epoxycyclohexyl) ethyl] tetramethyl disiloxane:

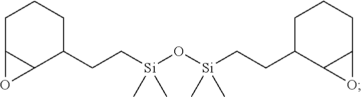 [SMILES: C[Si](C)(CCC1CCCC2OC12)O[Si](C)(C)CCC1CCCC2OC12]

1,3-bis(glycidoxypropyl)tetramethyl disiloxane:

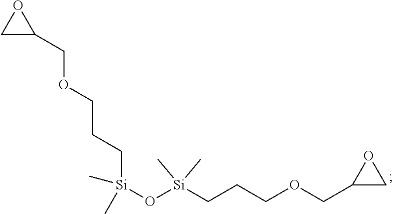 [SMILES: C[Si](C)(CCCOCC1CO1)O[Si](C)(C)CCCOCC1CO1]

3,4-epoxycyclohexylmethyl-3,4-epoxycyclo-hexanecarboxylate:

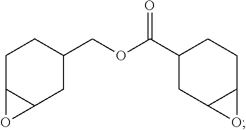 [SMILES: O=C(OCC1CCC2OC2C1)C1CCC2OC2C1]

bis((3,4-epoxycyclohexyl)methyl) adipate:

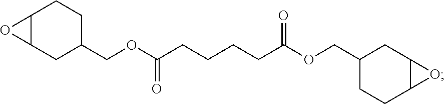 [SMILES: O=C(CCCCC(=O)OCC1CCC2OC2C1)OCC1CCC2OC2C1]

4-vinyl-1-cyclohexene 1,2-epoxide:

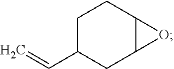

vinylcyclohexene dioxide:

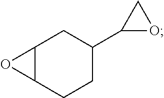

4,5-epoxytetrahydrophthalic acid diglycidyl ester:

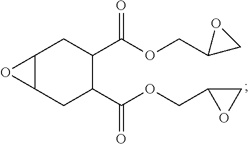 [SMILES: O=C(OCC1CO1)C1CC2OC2CC1C(=O)OCC1CO1]

1,2-epoxy-3-phenoxypropane:

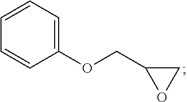 [SMILES: c1ccc(OCC2CO2)cc1]

glycidyl methacrylate:

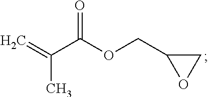

1,2-epoxyhexadecane:

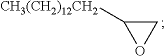

poly(ethylene glycol) diglycidylether:

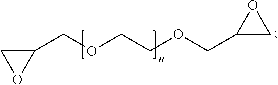

(wherein n ranges from 1 to 100);
pentaerythritol glycidyl ether:

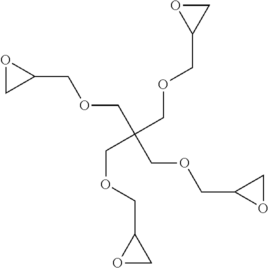 [SMILES: C(OCC(COCC1CO1)(COCC1CO1)COCC1CO1)C1CO1]

diglycidyl 1,2-cyclohexanedicarboxylate:

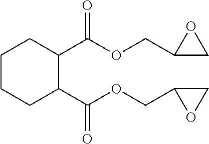 [SMILES: O=C(OCC1CO1)C1CCCCC1C(=O)OCC1CO1]

tetrahydrophthalic acid diglycidyl ester:

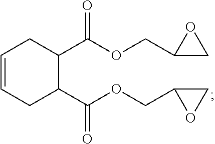 [SMILES: O=C(OCC1CO1)C1CC=CCC1C(=O)OCC1CO1]

and combinations thereof. When combinations are used, it is to be understood that any two or more of the listed epoxy resin materials may be used together in the resin composition.

In some embodiments, the epoxy functionalized silsesquioxane includes a silsesquioxane core that is functionalized with epoxy groups. In some embodiments, the imprint layer disclosed herein may comprise one or more different cage or core silsesquioxane structures as monomeric units. For example, the polyhedral structure may be a T₈ structure (a polyoctahedral cage or core structure), such as:

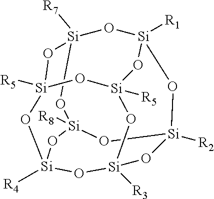

and represented by:

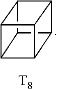

This monomeric unit typically has eight arms of functional groups R₁ through R₈. The monomeric unit may have a cage structure with 10 silicon atoms and 10 R groups, referred to as T₁₀, such as:

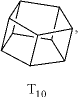

or may have a cage structure with 12 silicon atoms and 12 R groups, referred to as T₂, such as:

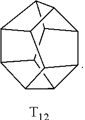

The silsesquioxane-based material may alternatively include T₆, T₁₄, or T₁₆ cage structures.

The average cage content can be adjusted during the synthesis, and/or controlled by purification methods, and a distribution of cage sizes of the monomeric unit(s) may be used in the examples disclosed herein. As examples, any of the cage structures may be present in an amount ranging from about 30% to about 100% of the total silsesquioxane monomeric units used. Thus, the silsesquioxane-based material may include a mixture of silsesquioxane configurations.

The silsesquioxane-based material may be a mixture of cage structures, and may include open and partially open cage structures. For example, any epoxy silsesquioxane material described herein may be a mixture of discrete silsesquioxane cages and non-discrete silsesquioxane structures and/or incompletely condensed, discrete structures, such as polymers, ladders, and the like. The partially condensed materials would include epoxy R groups as described herein at some silicon vertices, but some silicon atoms would not be substituted with the epoxy R groups and could be substituted instead with OH groups. In some examples, the silsesquioxane materials comprise a mixture of various forms, such as: (a) condensed cages

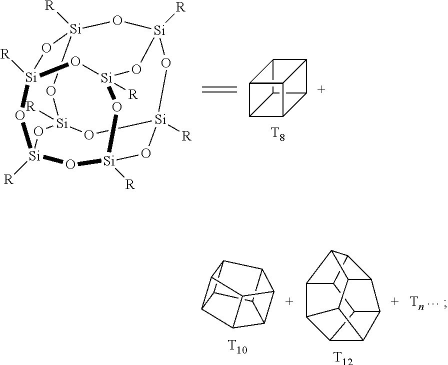

(b) incompletely condensed cages

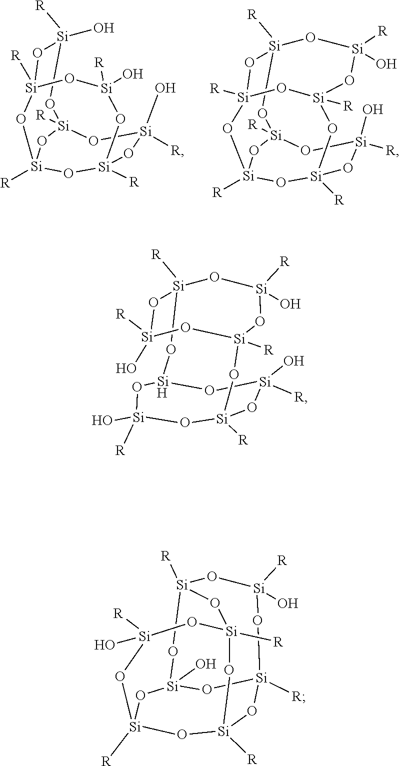

and/or
(c) non-cage content large and ill-defined structure

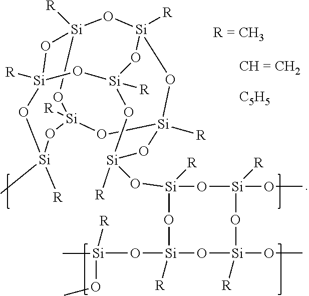

In the examples disclosed herein, at least one of R₁ through R₈ or R₁₀ or R₁₂ comprises an epoxy, and thus the silsesquioxane is referred to as an epoxy silsesquioxane (e.g., epoxy polyhedral oligomeric silsesquioxane). In some aspects, the epoxy silsesquioxane comprises terminal epoxy groups. An example of this type of silsesquioxane is glycidyl POSS having the structure:

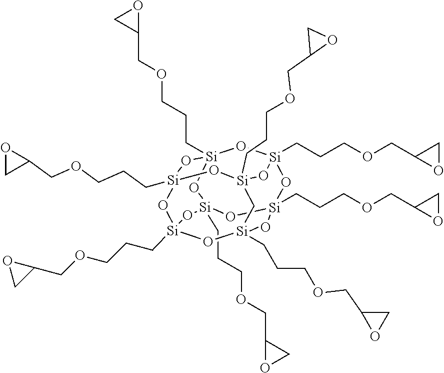 [SMILES: C(COCC1CO1)C[Si]12C[Si]3(CCCOCC4CO4)O[Si]4(CCCOCC5CO5)O[Si](CCCOCC5CO5)(O1)O[Si]1(CCCOCC5CO5)O[Si](CCCOCC5CO5)(O2)O[Si](CCCOCC2CO2)(O3)O[Si](CCCOCC2CO2)(O4)O1]

Another example of this type of silsesquioxane is epoxycyclohexyl ethyl functionalized POSS having the structure:

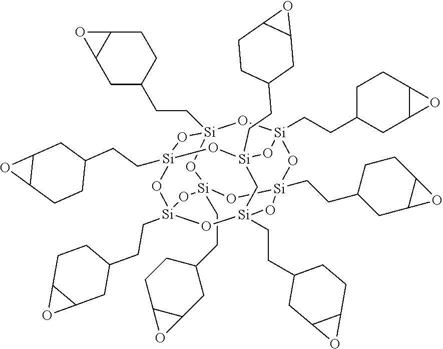 [SMILES: C1CC2OC2CC1CC[Si]12C[Si]3(CCC4CCC5OC5C4)O[Si]4(CCC5CCC6OC6C5)O[Si](CCC5CCC6OC6C5)(O1)O[Si]1(CCC5CCC6OC6C5)O[Si](CCC5CCC6OC6C5)(O2)O[Si](CCC2CCC5OC5C2)(O3)O[Si](CCC2CCC3OC3C2)(O4)O1]

One example of the epoxy resin matrix disclosed herein includes the epoxy functionalized polyhedral oligomeric silsesquioxane, where the epoxy functionalized polyhedral oligomeric silsesquioxane is selected from the group consisting of a glycidyl functionalized polyhedral oligomeric silsesquioxane, an epoxycyclohexyl ethyl functionalized polyhedral oligomeric silsesquioxane, and combinations thereof. This example may include the epoxy silsesquioxane material(s) alone, or in combination with an additional epoxy material selected from the group consisting of trimethylolpropane triglycidyl ether; tetrakis(epoxycyclohexyl ethyl)tetramethyl cyclotetrasiloxane; a copolymer of (epoxycyclohexylethyl)methylsiloxane and dimethylsiloxane; 1,3-bis[2-(3,4-epoxycyclohexyl) ethyl] tetramethyl disiloxane; 1,3-bis(glycidoxypropyl)tetramethyl disiloxane; 3,4-epoxycyclohexylmethyl-3,4-epoxycyclo-hexanecarboxylate; bis((3,4-epoxycyclohexyl)methyl) adipate; 4-vinyl-1-cyclohexene 1,2-epoxide; vinylcyclohexene dioxide; 4,5-epoxytetrahydrophthalic acid diglycidyl ester; 1,2-epoxy-3-phenoxypropane; glycidyl methacrylate; 1,2-epoxyhexadecane; poly(ethylene glycol) diglycidylether; pentaerythritol glycidyl ether; diglycidyl 1,2-cyclohexanedicarboxylate; tetrahydrophthalic acid diglycidyl ester; and combinations thereof.

In other silsesquioxane examples, a majority of the arms, such as the eight, ten, or twelve arms, or R groups, comprise epoxy groups. In other examples, R₁ through R₈ or R₁₀ or R₁₂ are the same, and thus each of R₁ through R₈ or R₁₀ or R₁₂ comprises an epoxy group. In still other examples, R₁ through R₈ or R₁₀ or R₁₂ are not the same, and thus at least one of R₁ through R₈ or R₁₀ or R₁₂ comprises epoxy and at least one other of R₁ through R₈ or R₁₀ or R₁₂ is a non-epoxy functional group, which in some cases is selected from the group consisting of an azide/azido, a thiol, a poly(ethylene glycol), a norbornene, and a tetrazine, or further, for example, alkyl, aryl, alkoxy, and haloalkyl groups. In some aspect, the non-epoxy functional group is selected to increase the surface energy of the resin. In these other examples, the ratio of epoxy groups to non-epoxy groups ranges from 7:1 to 1:7, or 9:1 to 1:9, or 11:1 to 1:11.

In the examples disclosed herein, the epoxy silsesquioxane may also be a modified epoxy silsesquioxane, that includes a controlled radical polymerization (CRP) agent and/or another functional group of interest incorporated into the resin or core or cage structure as one or more of the functional group R₁ through R₈ or R₁₀ or R₁₂.

Whether a single epoxy material or a combination of epoxy materials is used in the epoxy resin matrix, the total amount of the epoxy resin matrix in the resin composition ranges from about 93 mass % to about 99 mass % of the total solids.

With any of the example epoxy materials disclosed herein, it is to be understood that the epoxy group(s) allow the monomeric units and/or the copolymer to polymerize and/or cross-link into a cross-linked matrix upon initiation using ultraviolet (UV) light and acid.

Certain resins may be removable by wet etching. In some embodiments, such resins may be included in substrates, for example as a second resin layer. Suitable resins may include epoxy resins, acrylate resins, and thiol-ene resins. Monomers of such resins may include glycerol dimethacrylate mixture of isomers (GD2MA), petaerythritol triacrylate (PE3A), glycerol 1,3-diglycerolate diacrylate (GD2A), pentaerythritol tetraacrylate (PE4A), pentaerythritol tetrakis(3-mercaptopropionate) (4SH), 3,4-epoxycyclohexylmethyl 3,4-epoxycyclohexanecarboxylate (ECHC), trimethylolpropane triglycidyl ether (TTE), 2-hydroxy-2-methylpriopehenone (HMPP), diphenyl (2,4,6-trimethylbenzoyl)phosphine oxide (DPBAPO), ethyl (2,4,6-trimethylbenzoyl) phenyl phosphinate (TPO-L), bis(4-methylphenyl)iodonium hexafluorphosphate (IPF), and/or tris (4-((4-acetylphenyl thio)phenyl)-sulfonium tetrakis (perfluoro-phenyl) borate (PAG290).

### Blocking Light Transmission by Absorption

In some embodiments of the substrates and methods described herein, a resin layer includes an agent capable of absorbing light. In some embodiments, the second resin layer includes an agent capable of absorbing light. In some further embodiments, the resin layer includes an agent capable of absorbing UV light. The absorbance of the resin layer including the light-absorbing agent may depend at least in part on the concentration of the light-absorbing agent within the resin layer.

In some embodiments of the imprint layer described herein, a resin layer (e.g., the second resin layer) of the imprint layer may be capable of blocking light, for example by absorption. The resin layer may include one or more photoacid generators (PAGs) and/or one or more photo initiators (PIs), or combinations thereof. Photoacid generators are organic compounds that can generate protons (H⁺) upon irradiation with certain wavelengths of light. Photo initiators are molecules that create reactive species (free radicals, cations, or anions) when exposed to radiation (UV or visible light). The one or more PAG(s) may be selected from the group including bis(4-methylphenyl)iodonium hexafluorophosphate, tris(4-((4-acetylphenyl)thio)phenyl)-sulfonium tetrakis(perfluorophenyl)borate, 2-isopropylthioxanthone, cationic epoxy silicone (for example, TEGO® Photo Compound 1467), 1-naphthyl diphenylsulfonium triflate, diaryliodonium hexafluorophosphate, diaryliodonium hexafluoroantimonate, (4-phenylthiophenyl)diphenylsulfonium triflate, bis(2,4,6-trimethylphenyl)iodonium triflate, and bis(4-tert-butylphenyl)iodonium hexafluorophosphate. In some embodiments, the imprint layer includes about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, 10%, 12%, 14%, 16%, 18% or 20% by weight of PAG(s), or a range defined by any two of the preceding values. In some embodiments, the imprint layer includes from about 0.1% to about 20% PAG(s) by weight, about 0.5% to about 15% PAG(s) by weight, about 1% to about 10% PAG(s) by weight, about 2% to about 9% PAG(s) by weight, about 3% to about 8% PAG(s) by weight, about 4% to about 7% PAG(s) by weight, or about 4% to about 6% PAG(s) by weight. In some embodiments, the imprint layer includes at least 0.1%, 0.5%, 1%, 2%, 3%, 4%, 5%, 6%, 7%, 8%, 9% or 10% of PAG(s) by weight, though in some instances other values or ranges may be used. The PI(s) may be selected from the group including diphenyl(2,4,6-trimethylbenzoyl)phosphine oxide, 2-benzyl-2-(dimethylamino)-4′-morpholinobutyrophenone, 2,2-dimethoxy-2-phenylacetophenone, 2-ethyl-9,10-dimethoxyanthracene, phenylbis(2,4,6-trimethylbenzoyl)phosphine oxide, ethyl(2,4,6-trimethylbenzoyl) phenylphosphinate, 4,4′-bis(diethylamino)benzophenone, benzoin ethyl ether, 2,2-diethoxyacetophenone, and 4′-phenoxyacetophenone. In some embodiments, the imprint layer includes about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, 10%, 12%, 14%, 16%, 18% or 20% by weight of PI(s), or a range defined by any two of the preceding values. In some embodiments, the imprint layer includes from about 0.1% to about 20% PI(s) by weight, about 0.5% to about 15% PI(s) by weight, about 1% to about 10% PI(s) by weight, about 2% to about 9% PI(s) by weight, about 3% to about 8% PI(s) by weight, about 4% to about 7% PI(s) by weight, or about 4% to about 6% PI(s) by weight. In some embodiments, the imprint layer includes at least 0.1%, 0.5%, 1%, 2%, 3%, 4%, 5%, 6%, 7%, 8%, 9% or 10% of PI(s) by weight, though in some instances other values or ranges may be used.

In some embodiments, an agent may be added to a resin layer of the imprint layer to increase light absorption of the resin layer. The agent may also be referred to as a “dopant” herein. Table 1 lists example light-absorbing agents and the wavelength ranges at which each of the agents is capable of absorbing light.

TABLE 1
Example light-absorbent agents.

| | Absorbance |
|---|---|
| Name of additive | range/nm |
| ZnO particles | 200-400 |
| ZrO₂ particles | 200-400 |
| TiO₂ particles | 200-400 |
| Epoxy compounds of ZnO, ZrO₂, TiO₂ | 200-400 |
| Photoinitiator [PI] | 220-400 |
| Photoacid generator [PAG] | 220-400 |
| Quenchers (e.g., Black Hole Quenchers ™) | 250-800 |
| Carbon particles | 250-800 |
| Avobenzone | 250-400 |
| Bisoctrizole | 260-400 |
| Bismotriznol | 260-400 |
| Meradimate | 250-350 |
| Dioxybenzone | 300-400 |
| Oxybenzone | 280-355 |
| Drometrizole | 300-400 |
| 4-Methacryloxy-2-hydroxybenzophenone | 200-350 |
| 2,2-dihydroxy, 4-methoxybenzophenone | 330-370 |
| Drometrizole trisiloxane | 260-400 |
| 2,2-dihydroxy, 4-methoxybenzophenone | 330-370 |
| Methyl-2-cyan-3-(4-hydroxyphenyl)acrylate | 200-400 |
| (E)-Ethyl 2-(3-ethoxy-4-hydroxybenzylidene)- | 200-400 |
| 3-oxobutanoate | |
| Ethyl-2-cyano-3-(4-hydroxy-3-methoxy phenyl)acrylate | 200-400 |
| Dimethyl 2-(4-hydroxybenzylidene)malonate | 200-400 |

In some embodiments, the second resin layer of the imprint layer may include TiO₂ nanoparticles. In such embodiments, the second resin layer may include 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, or 25% TiO₂ nanoparticles by weight, or in a range defined by any two of the preceding values. In some embodiments, the second resin layer's percentage of TiO₂ by weight is from 1.25% to 15%. In some embodiments, the second resin layer's percentage of TiO₂ by weight is from 5% to 15%. In some embodiments, the second resin layer's percentage of TiO₂ by weight is from 10% to 15%. In some embodiments, the TiO₂ nanoparticles have a diameter of 1, 2, 3, 4, 5, 6, 7, 8, 9, 10, 15, 20, 25, 30, 35, 40, 45, 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, or 200 nm, or in a range defined by any two of the preceding values. In some embodiments, the diameter of the TiO₂ nanoparticles is from about 5 nm to about 150 nm. In some embodiments, the diameter of the TiO₂ nanoparticles is from about 10 nm to about 150 nm. In some embodiments, the diameter of the TiO₂ nanoparticles is from about 10 nm to about 100 nm. In some embodiments, the diameter of the TiO₂ nanoparticles is from about 50 nm to about 150 nm. In some embodiments, the diameter of the TiO₂ nanoparticles is from about 80 nm to about 120 nm. In some embodiments, the diameter of the TiO₂ nanoparticles is from about 90 nm to about 110 nm. In some embodiments, the diameter of the TiO₂ nanoparticles is from about 5 nm to about 30 nm.

In some embodiments, the second resin layer of the imprint layer may include Zn-conjugated acrylate. In some embodiments, the second resin layer may about 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, or 50% Zn-conjugated acrylate by weight or in a range defined by any two of the preceding values. In some embodiments, the second resin layer may include from about 10% to about 40% Zn-conjugated acrylate by weight.

In some embodiments, the second resin layer of the imprint layer may include bisoctrizole. In some embodiments, the second resin layer may about 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, or 30% bisoctrizole by weight or in a range defined by any two of the preceding values. In some embodiments, the second resin layer may include from about 1% to about 15% bisoctrizole by weight.

In some embodiments, the second resin layer of the imprint layer may include avobenzone. In some embodiments, the second resin layer may about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, or 50% avobenzone by weight or in a range defined by any two of the preceding values. In some embodiments, the second resin layer may include from about 0.5% to about 30% avobenzone by weight.

Resin layers of the imprint layer may include one or more leveling agents (LAs). In some embodiments, the leveling agent is used to enhance the thickness uniformity of the imprint layer. In further embodiments, the leveling agent includes a polyacrylate or a polyacrylate co-polymer. In yet further embodiments, the leveling agent is selected from the group consisting of BYK-350 (BYK-Chemie GmbH), BYK-394 (BYK-Chemie GmbH), BYK-354 (BYK-Chemie GmbH), BYK-392 (BYK-Chemie GmbH), BYK-352 (BYK-Chemie GmbH), BYK-356 (BYK-Chemie GmbH), and BYK-359 (BYK-Chemie GmbH), all of which are polyacrylate-based surface additive for solvent-borne and/or solvent-free coatings. In some embodiments, the imprint layer comprises about 0.1%, 0.2%, 0.3%, 0.4%, 0.5%, 0.6%, 0.7%, 0.8%, 0.9%, 1.0%, 1.1%, 1.2%, 1.3%, 1.4%, 1.5%, 1.6%, 1.7%, 1.8%, 1.9%, 2.0%, 2.1%, 2.2%, 2.3%, 2.4%, 2.5%, 2.6%, 2.7%, 2.8%, 2.9%, 3.0%, 3.1%, 3.2%, 3.3%, 3.4%, 3.5%, 3.6%, 3.7%, 3.8%, 3.9%, 4.0%, 4.1%, 4.2%, 4.3%, 4.4%, 4.5%, 4.6%, 4.7%, 4.8%, 4.9%, 5.0%, 5.5%, 6.0%, 6.5%, 7.0%, 7.5%, 8.0%, 8.5%, 9.0%, 9.5%, or 10% leveling agent(s) by weight, or a range defined by any two of the preceding values. In some embodiments, the imprint layer includes from about 0.1% to about 10% LA(s) by weight, about 0.5% to about 8% LA(s) by weight, about 1% to about 6% LA(s) by weight, or about 1.5% to about 4% LA(s) by weight. In some embodiments, the imprint layer includes at least 0.1%, 0.2%, 0.4%, 0.6%, 0.8%, 1%, 1.2%, 1.4%, 1.6%, 1.8%, 2%, 3.0%, 4.0% 5%, 6%, 7%, 8%, 9% or 10% of LA(s) by weight, though in some instances other values or ranges may be used.

### Photoresist

In one aspect, the present disclosure provides materials for inclusion in a photoresist. In some embodiments, the photoresist is a negative photoresist. In some examples, photoresist material may include NR9-150 (Futurrex, Inc.) and/or NR9-1500 (Futurrex, Inc.), both of which are negative resists. For example, NR9-1500 is a negative lift-off resist optimized for 365 nm wavelength exposure and effective for brand-band exposure.

In some embodiments, the photoresist is a positive photoresist. In some examples, photoresist material may include azide quinone, and/or phonolic novolak resins, both of which are positive resists.

### Methods of Functionalizing Patterned Substrates

Another aspect of the present disclosure relates to a method for functionalizing a surface of a patterned substrate, comprising:
depositing a first functionalized molecule on a patterned substrate in accordance with the present disclosure, wherein the first functionalized molecule covers the top surface of the second resin layer and the surfaces of at least a portion of the deep wells and the shallow wells of the plurality multi-level depressions;
introducing a photoresist into the multi-level depressions of the substrate;
exposing the substrate to light from a backside of the base support opposite to the imprint layer such that only the photoresist residing within the deep wells of the multi-level depressions are cured, and the photoresist residing within the shallow wells of the multi-level depressions remains unexposed to light and uncured; and
removing the uncured photoresist from the substrate.

Another aspect of the present disclosure relates to a method for functionalizing a surface of a patterned substrate, comprising:
depositing a first functionalized molecule on a patterned substrate of the present disclosure having a third resin layer, wherein the first functionalized molecule covers the top surface of the third resin layer and the surfaces of at least a portion of the deep wells and the shallow wells of the plurality multi-level depressions;
introducing a photoresist into the multi-level depressions of the substrate;
exposing the substrate to light from a backside of the base support opposite to the imprint layer such that only the photoresist residing within the deep wells of the multi-level depressions are cured, and the photoresist residing within the shallow wells of the multi-level depressions remains unexposed to light and uncured; and
removing the uncured photoresist from the substrate.

In some embodiments, the method further comprises:
etching the imprint layer to remove the second resin layer and to form a third inner well surface in each of the shallow wells, wherein the third inner well surface resides within the first resin layer, and the third inner well surface is parallel to the base support;
depositing a second functionalized molecule on the first resin layer to cover at least a portion of the third inner well surfaces and the cured photoresist; and
removing the cured photoresist from the substrate;
wherein the first functionalized molecule remains on at least a portion of the first inner well surfaces and the second functionalized molecule remains on at least a portion of the third inner well surfaces.

In some embodiments, the method further comprises polishing the first resin layer, wherein the polishing removes the second functionalized molecule from interstitial regions of the first resin layer. In some embodiments, etching removes the step portion between each deep well and shallow well. In some embodiments, the etching step comprises both dry etching and wet etching. In some embodiments, the method does not include a polish step prior to the depositing of the second functionalized molecule. In some embodiments, exposing the substrate to light comprises exposing the substrate to UV light, the first resin layer configured to allow passage of the UV light, and the second resin layer configured as a photomask for UV light such that the photoresist residing within the shallow portion of the multi-level depressions remains uncured. In some embodiments where the substrate has a first resin layer, a second resin layer, and a third resin layer, the etching step removes the third resin layer.

Another aspect of the present disclosure relates to a method for functionalizing a surface of a patterned substrate comprising a plurality of multi-level depressions, comprising:
introducing a photoresist into the multi-level depressions of the patterned substrate in accordance with the present disclosure;
exposing the substrate to light from a backside of the base support opposite to the imprint layer such that only the photoresist residing within the deep wells of the multi-level depressions is cured, and the photoresist residing within the shallow wells of the multi-level depressions remains unexposed to light and uncured;
removing the uncured photoresist from the substrate;
etching the imprint layer to remove the second resin layer and to form a third inner well surface in each of the shallow wells, wherein the third inner well surface resides within the first resin layer, and the third inner well surface is parallel to the base support;
depositing a first functionalized molecule on the first resin layer to cover at least a portion of the third inner well surfaces and the cured photoresist;
removing the cured photoresist from the substrate, thereby exposing the first inner well surfaces; and
depositing a second functionalized molecule on the first inner well surfaces.

In some embodiments, the method further comprises polishing the first resin layer, wherein the polishing removes the first functionalized molecule and the second functionalized molecule from interstitial regions of the first resin layer. In some embodiments, the etching step removes the step portion between each deep well and shallow well. In some embodiments, the etching step comprises both dry etching and wet etching. In some embodiments, the exposing the substrate to light comprises exposing the substrate to UV light, the first resin layer configured to allow passage of the UV light, and the second resin layer configured as a photomask for UV light such that the photoresist residing within the shallow portion of the multi-level depressions remains uncured. In some embodiments where the substrate has a first resin layer, a second resin layer, and a third resin layer, the etching step removes the third resin layer.

Another aspect of the present disclosure relates to a method for functionalizing a surface of a patterned substrate comprising a plurality of multi-level depressions, comprising:
introducing a positive photoresist into the multi-level depressions of the patterned substrate according to the present disclosure;
exposing the substrate to light from a backside of the base support opposite to the imprint layer such that only the photoresist residing within the deep wells of the multi-level depressions is exposed to light, and the photoresist residing within the shallow wells of the multi-level depressions remains unexposed to light;
removing light exposed photoresist from the substrate;
depositing a functionalized molecule on the imprint layer of the substrate to cover at least a portion of the first inner well surfaces;
removing the second resin layer and remaining unexposed positive photoresist by etching.

In any embodiments of the methods described herein, the remaining positive photoresist and the second resin layer are removed by wet etching. In some embodiments, the exposing the substrate to light comprises exposing the substrate to UV light, the first resin layer configured to allow passage of the UV light, and the second resin layer is a photomask for UV light. In some embodiments, the method does not include a polish step. In some embodiments, the method includes dry etching the second resin layer. In some embodiments, the second resin layer is wet etchable. In some embodiments, the second resin layer is both wet etchable and dry etchable. In some embodiments, the first resin layer is not wet etchable. In some embodiments, the method includes dry etching the first resin layer. In some embodiments, the second resin layer comprises an epoxy resin and one or more light-absorbing agents. In some further embodiments, the epoxy resin comprises at least one of 3,4-epoxycyclohexylmethyl 3,4-epoxycyclohexanecarboxylate (ECHC), trimethylolpropane triglycidyl ether (TTE), BIS(4-methylphenyl)iodonium hexafluorophosphate (IPF), tris (4-((4-acetylphenyl)thio)phenyl)-sulfonium tetrakis(perfluoro-phenyl) borate (PAG290), or diphenyl (2,4,6-trimethylbenzoyl)phosphine oxide (DPBAPO). In some further embodiments, the one or more light-absorbing agents in the second resin layer comprises one or more UV-absorbing agents. In some further embodiments, the UV-absorbing agents are selected from the group consisting of ZnO nanoparticles, TiO₂ nanoparticles, ZrO₂ nanoparticles, Zn-conjugated acrylate, Ti-conjugated acrylate, Zr-conjugated acrylate, Zn-conjugated epoxy, Ti-conjugated epoxy, Zr-conjugated epoxy, carbon black, photo initiator (PI), photoacid generator (PAG), quencher dye, poly(pyrrole), poly(thiophene), poly(phenylene), dithiomaleimide and dibromomaleimide, avobenzone, bisoctrizole, meradimate, dioxybenzone, oxybenzone, drometrizole, 4-methacryloxy-2-hydroxybenzophenone, 2,2-dihydroxy, 4-methoxybenzophenone, methyl-2-cyan-3-(4-hydroxyphenyl)acrylate, (E)-ethyl 2-(3-ethoxy-4-hydroxybenzylidene)-3-oxobutanoate, ethyl-2-cyano-3-(4-hydroxy-3-methoxy phenyl)acrylate, and dimethyl 2-(4-hydroxybenzylidene)malonate, and combinations thereof. In some embodiments, the second resin layer comprises an acrylate resin and one or more light-absorbing agents. In some further embodiments, the acrylate resin comprises at least one of pentaerythritol triacrylate (PE3A) or diphenyl (2,4,6-trimethylbenzoyl)phosphine oxide (DPBAPO). In some embodiments, the second resin layer includes at least one leveling agent. In some further embodiments, the leveling agent is selected from the group consisting of BYK-350 (BYK-Chemie GmbH), BYK-394 (BYK-Chemie GmbH), BYK-354 (BYK-Chemie GmbH), BYK-392 (BYK-Chemie GmbH), BYK-352 (BYK-Chemie GmbH), BYK-356 (BYK-Chemie GmbH), and BYK-359 (BYK-Chemie GmbH), and combinations thereof. In some further embodiments, the second resin layer comprises TiO₂ nanoparticles. In yet further embodiments, the TiO₂ nanoparticles have a diameter from about 50 nm to about 150 nm. In some further embodiments, the second resin layer comprises from about 1% to about 15% TiO₂ nanoparticles by weight. In some embodiments, the second resin layer comprises from about 10% to about 40% Zn-conjugated acrylate by weight. In some embodiments, the second resin layer comprises from about 1% to about 15% bisoctrizole by weight. In some embodiments, the second resin layer comprises from about 0.5% to about 30% avobenzone by weight. In some embodiments, a thickness of the second resin layer defined between the first resin layer and a top surface of the second resin layer is between about 20 nm and about 1 μm. In some embodiments where the substrate has a first resin layer, a second resin layer, and a third resin layer, the etching step removes the third resin layer.

### Example SPEAR Substrate Workflow 1

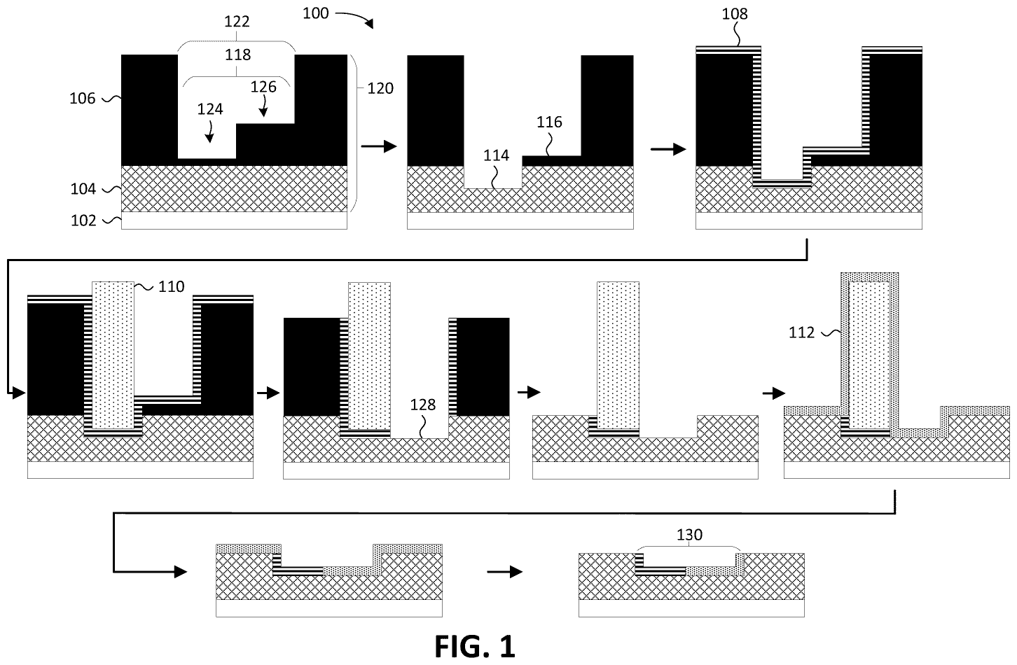

FIG. 1 illustrates an exemplary workflow 100 for creating a SPEAR substrate (e.g., flow cell) surface. A first resin layer 104 may be layered over the base support 102. A second resin layer 106 may be layered over the first resin layer 104. Together, the first resin layer 104 and second resin layer 106 may form an imprint layer 120. A working stamp may contact the imprint layer 120 to form a plurality of multi-level depressions 122. Each of the plurality of multi-level depressions 122 may include a step portion 118 defining a deep well 124 and a shallow well 126. In accordance with the present disclosure, the first resin layer 104 can permit passage of light. In accordance with the present disclosure, the second resin layer 106 can block light, for example by absorbing light.

The substrate may be subject to etching, for example dry etching, which may expose a first surface 114, residing in the first resin layer 104, and a second surface 116, residing within the second resin layer 106. The first surface 114 may be parallel to the base support 102 and within the deep well 124. The second surface 116 may be parallel to the base support 102 and within the shallow well 126.

A first functionalized molecule 108 may be deposited over the imprint layer 120. The first functionalized molecule 108 may cover at least a portion of the first surface 114 and the second surface 116.

A photoresist may be introduced to the substrate. The substrate may be exposed to light from the backside of the of the base support 102 (i.e., the side of the base support 102 opposite the imprint layer 120). The first resin layer 104 can allow passage of light to the deep well 124, but the second resin layer 106 can block light, preventing light from reaching the shallow well 126 and interstitial regions of the substrate (i.e., regions between each of the plurality of multi-level depressions 122). Exposure to light can cure the photoresist 110 residing within the deep well 124 of each of the plurality of multi-level depressions 122. The photoresist 110 may cover the first functionalized molecule 108 on the first surface 114. In some embodiments, the photoresist 110 is a negative photoresist. Uncured photoresist may be removed.

The substrate may be subjected to etching to expose a third surface 128. The third surface 128 may reside within the first resin layer 104 and may be parallel to the base support 102. In some embodiments, the substrate may be etched to remove some material from the first resin layer 104, thereby exposing the third surface 128. The third surface 128 may be at the same depth as the first surface 114. In some embodiments, some of the second resin layer 106 may be removed. The etching may be dry etching.

The second resin layer 106 may be removed from the substrate. The substrate may be subjected to etching to remove the second resin layer 106. In some embodiments, the second resin layer 106 can be removed by wet etching.

A second functionalized molecule 112 may be deposited over the substrate. The second functionalized molecule 112 may cover at least a portion of the third surface 128, as well as covering the photoresist 110 and interstitial regions of the substrate.

The photoresist 110 may be removed from the substrate. The photoresist 110 may be removed by a photoresist stripping process. Removal of the photoresist 110 may expose the first functionalized molecule 108 on the first surface 114.

The substrate may undergo a polish step, thereby removing the second functionalized molecule 112 from the interstitial regions of the substrate. The remaining first functionalized molecule 108 and second functionalized molecule 112 may be found within the nanowell 130.

### Example SPEAR Substrate Workflow 2

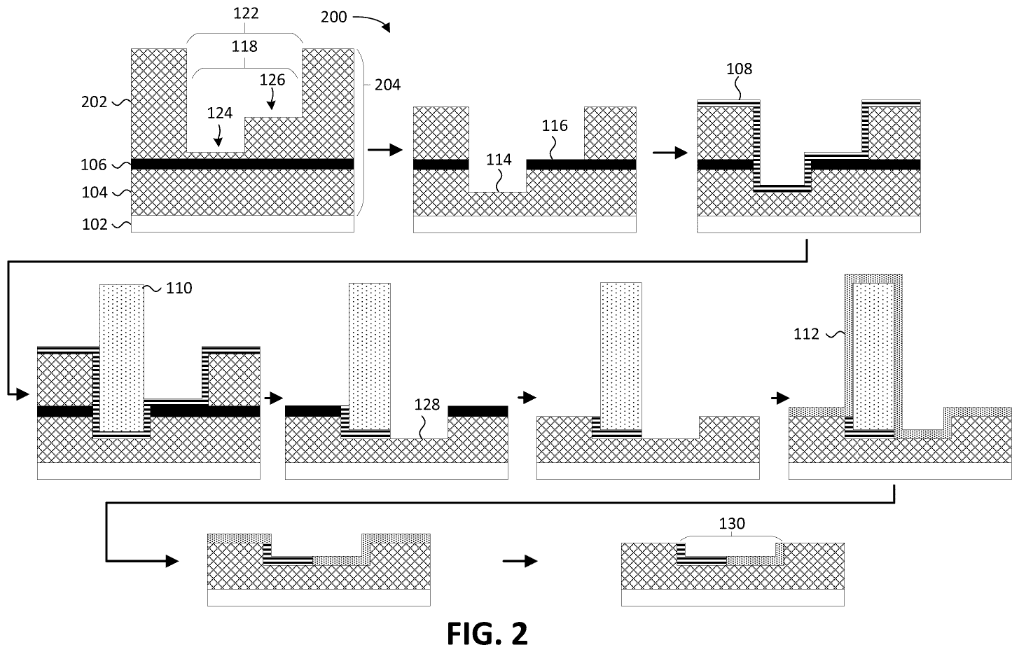

FIG. 2 illustrates an exemplary workflow 200 for creating a SPEAR substrate (e.g., flow cell) surface. A first resin layer 104 may be layered over the base support 102. A second resin layer 106 may be layered over the first resin layer 104. A third resin layer 202 may be layered over the second resin layer 106. Together, the first resin layer 104, second resin layer 106, and third resin layer 202 may form an imprint layer 204. A working stamp may contact the imprint layer 204 to form a plurality of multi-level depressions 122. Each of the plurality of multi-level depressions 122 may include a step portion 118 defining a deep well 124 and a shallow well 126. In accordance with the present disclosure, the first resin layer 104 can permit passage of light. In accordance with the present disclosure, the second resin layer 106 can block light, for example by absorbing light. In accordance with the present disclosure, the third resin layer 202 can permit passage of light. In some embodiments, the material of the first resin layer 104 and the third resin layer 202 may be the same.

The substrate may be subject to etching, for example dry etching, which may expose a first surface 114, residing in the first resin layer 104, and a second surface 116, residing within the second resin layer 106 or the third resin layer 202. The first surface 114 may be parallel to the base support 102 and within the deep well 124. The second surface 116 may be parallel to the base support 102 and within the shallow well 126.

A first functionalized molecule 108 may be deposited over the imprint layer 204. The first functionalized molecule 108 may cover at least a portion of the first surface 114 and the second surface 116.

A photoresist may be introduced to the substrate. The substrate may be exposed to light from the backside of the of the base support 102 (i.e., the side of the base support 102 opposite the imprint layer 204). The first resin layer 104 can allow passage of light to the deep well 124, but the second resin layer 106 can block light, preventing light from reaching the shallow well 126 and interstitial regions of the substrate (i.e., regions between each of the plurality of multi-level depressions 122). Exposure to light can cure the photoresist 110 residing within the deep well 124 of each of the plurality of multi-level depressions 122. The photoresist 110 may cover the first functionalized molecule 108 on the first surface 114. In some embodiments, the photoresist 110 is a negative photoresist. Uncured photoresist may be removed.

The substrate may be subjected to etching to remove the third resin layer 202 and to expose a third surface 128. The third surface 128 may reside within the first resin layer 104 and may be parallel to the base support 102. In some embodiments, the third resin layer 202 can be removed by the same etching step that reveals the third surface 128. In some embodiments, the third resin layer 202 can be removed by dry etching. The third surface 128 may be at the same depth as the first surface 114. In some embodiments, the substrate may be dry etched to remove some material from the first resin layer 104. In some embodiments, dry etching may expose the third surface 128.

The second resin layer 106 may be removed from the substrate. The substrate may be subjected to etching to remove the second resin layer 106. In some embodiments, the second resin layer 106 can be removed by wet etching.

A second functionalized molecule 112 may be deposited over the substrate. The second functionalized molecule 112 may cover at least a portion of the third surface 128, as well as covering the photoresist 110 and interstitial regions of the substrate.

The photoresist 110 may be removed from the substrate. The photoresist 110 may be removed by a photoresist stripping process. Removal of the photoresist 110 may expose the first functionalized molecule 108 on the first surface 114.

The substrate may undergo a polish step, thereby removing the second functionalized molecule 112 from the interstitial regions of the substrate. The remaining first functionalized molecule 108 and second functionalized molecule 112 may be found within the nanowell 130.

### Example SPEAR Substrate Workflow 3

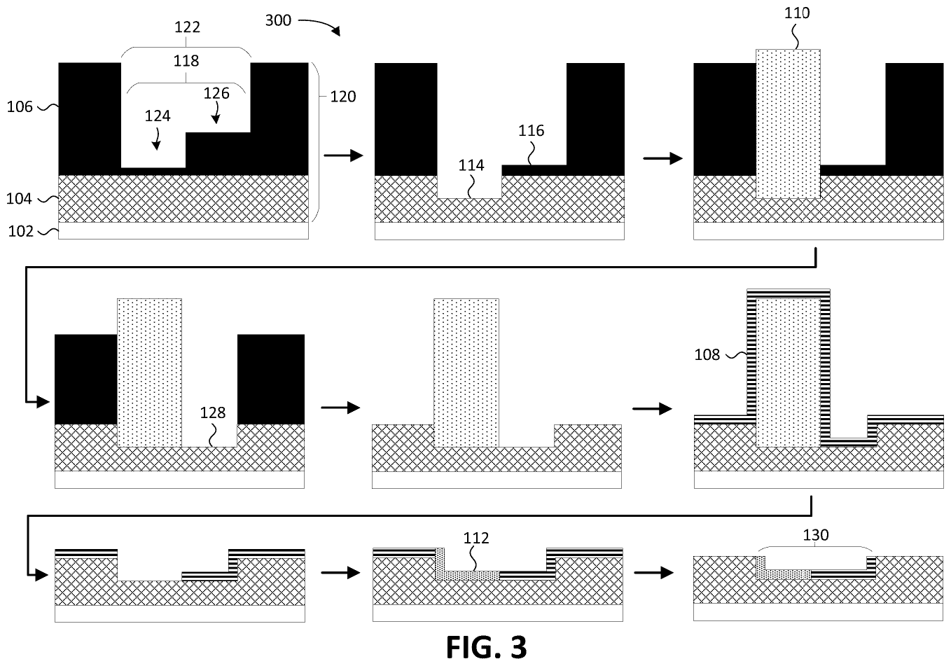

FIG. 3 illustrates an exemplary workflow 300 for creating a SPEAR substrate (e.g., flow cell) surface. A first resin layer 104 may be layered over the base support 102. A second resin layer 106 may be layered over the first resin layer 104. Together, the first resin layer 104 and second resin layer 106 may form an imprint layer 120. A working stamp may contact the imprint layer 120 to form a plurality of multi-level depressions 122. Each of the plurality of multi-level depressions 122 may include a step portion 118 defining a deep well 124 and a shallow well 126. In accordance with the present disclosure, the first resin layer 104 can permit passage of light. In accordance with the present disclosure, the second resin layer 106 can block light, for example by absorbing light.

The substrate may be subject to etching, for example dry etching, which may expose a first surface 114, residing in the first resin layer 104, and a second surface 116, residing within the second resin layer 106. The first surface 114 may be parallel to the base support 102 and within the deep well 124. The second surface 116 may be parallel to the base support 102 and within the shallow well 126.

A photoresist may be introduced to the substrate. The substrate may be exposed to light from the backside of the of the base support 102 (i.e., the side of the base support 102 opposite the imprint layer 120). The first resin layer 104 can allow passage of light to the deep well 124, but the second resin layer 106 can block light, preventing light from reaching the shallow well 126 and interstitial regions of the substrate (i.e., regions between each of the plurality of multi-level depressions 122). Exposure to light can cure the photoresist 110 residing within the deep well 124 of each of the plurality of multi-level depressions 122. In some embodiments, the photoresist 110 is a negative photoresist. Uncured photoresist may be removed.

The substrate may be subjected to etching to expose a third surface 128. The third surface 128 may reside within the first resin layer 104 and may be parallel to the base support 102. The third surface 128 may be at the same depth as the first surface 114. In some embodiments, the substrate may be dry etched to remove some material from the first resin layer 104, thereby exposing the third surface 128.

The second resin layer 106 may be removed from the substrate. The substrate may be subjected to etching to remove the second resin layer 106. In some embodiments, the second resin layer 106 can be removed by wet etching.

A first functionalized molecule 108 may be deposited over the photoresist 110 and the first resin layer 104 to cover at least a portion of the third surface 128, as well as covering interstitial regions of the substrate.

The photoresist 110 may be removed from the substrate. The photoresist 110 may be removed by a photoresist stripping process. Removal of the photoresist 110 may expose the first surface 114.

A second functionalized molecule 112 may be deposited over the substrate. The second functionalized molecule 112 may cover at least a portion of the first surface 114.

The substrate may undergo a polish step, thereby removing the first functionalized molecule 108 from the interstitial regions of the substrate. The remaining first functionalized molecule 108 and second functionalized molecule 112 may be found within the nanowell 130.

### Example SPEAR Substrate Workflow 4

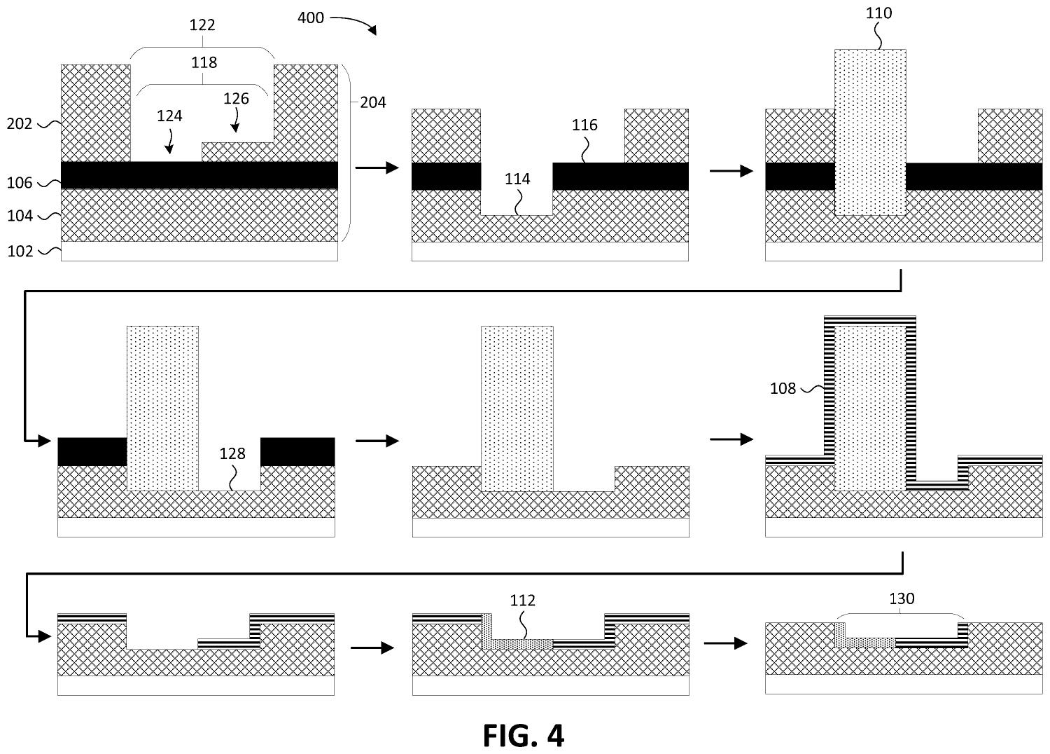

FIG. 4 illustrates an exemplary workflow 400 for creating a SPEAR substrate (e.g., flow cell) surface. A first resin layer 104 may be layered over the base support 102. A second resin layer 106 may be layered over the first resin layer 104. A third resin layer 202 may be layered over the second resin layer 106. Together, the first resin layer 104, second resin layer 106, and third resin layer 202 may form an imprint layer 204. A working stamp may contact the imprint layer 204 to form a plurality of multi-level depressions 122. Each of the plurality of multi-level depressions 122 may include a step portion 118 defining a deep well 124 and a shallow well 126. In accordance with the present disclosure, the first resin layer 104 can permit passage of light. In accordance with the present disclosure, the second resin layer 106 can block light, for example by absorbing light. In accordance with the present disclosure, the third resin layer 202 can permit passage of light. In some embodiments, the material of the first resin layer 104 and the third resin layer 202 may be the same.

The substrate may be subject to etching, for example dry etching, which may expose a first surface 114, residing in the first resin layer 104, and a second surface 116, residing within the second resin layer 106 or the third resin layer 202. The first surface 114 may be parallel to the base support 102 and within the deep well 124. The second surface 116 may be parallel to the base support 102 and within the shallow well 126.

A photoresist may be introduced to the substrate. The substrate may be exposed to light from the backside of the of the base support 102 (i.e., the side of the base support 102 opposite the imprint layer 204). The first resin layer 104 can allow passage of light to the deep well 124, but the second resin layer 106 can block light, preventing light from reaching the shallow well 126 and interstitial regions of the substrate (i.e., regions between each of the plurality of multi-level depressions 122). Exposure to light can cure the photoresist 110 residing within the deep well 124 of each of the plurality of multi-level depressions 122 and such that the cured photoresist 110 covers the first surface 114. In some embodiments, the photoresist 110 is a negative photoresist. Uncured photoresist may be removed.

The third resin layer 202 may be removed from the substrate. The substrate may be subjected to etching to remove the third resin layer 202 and to expose a third surface 128. The third surface 128 may reside within the first resin layer 104 and may be parallel to the base support 102. The third surface 128 may be at the same depth as the first surface 114. In some embodiments, the third resin layer 202 can be removed by the same etching step that reveals the third surface 128. In some embodiments, the third resin layer 202 can be removed by dry etching. In some embodiments, the substrate may be dry etched to remove some material from the first resin layer 104, exposing the third surface 128.

The second resin layer 106 may be removed from the substrate. In some embodiments, the second resin layer 106 can be removed by wet etching.

A first functionalized molecule 108 may be deposited over the photoresist 110 and the first resin layer 104 to cover at least a portion of the third surface 128, as well as covering interstitial regions of the substrate.

The photoresist 110 may be removed from the substrate. The photoresist 110 may be removed by a photoresist stripping process. Removal of the photoresist 110 may expose the first surface 114.

A second functionalized molecule 112 may be deposited over the substrate. The second functionalized molecule 112 may cover at least a portion of at least a portion of the first surface 114.

The substrate may undergo a polish step, thereby removing the second functionalized molecule 112 from the interstitial regions of the substrate. The remaining first functionalized molecule 108 and second functionalized molecule 112 may be found within the nanowell 130.

### Example Polish-Free Substrate Workflow 1

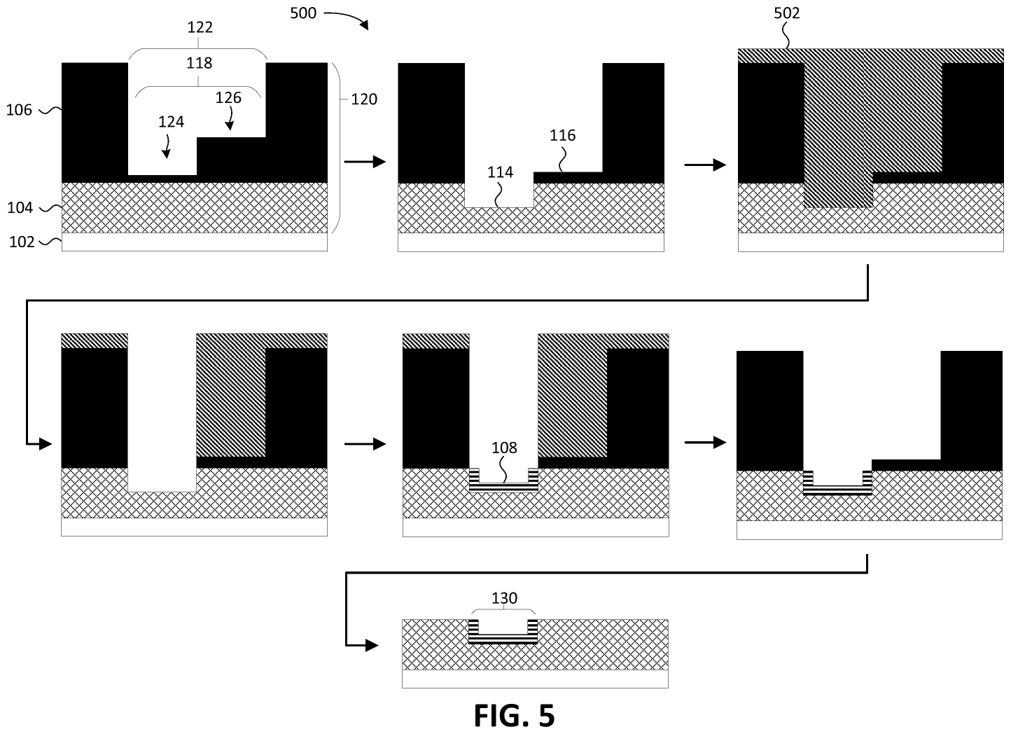

FIG. 5 illustrates an exemplary polish-free workflow 500 for creating a substrate (e.g., flow cell) surface. A first resin layer 104 may be layered over the base support 102. A second resin layer 106 may be layered over the first resin layer 104. Together, the first resin layer 104 and second resin layer 106 may form an imprint layer 120. A working stamp may contact the imprint layer 120 to form a plurality of multi-level depressions 122. Each of the plurality of multi-level depressions 122 may include a step portion 118 defining a deep well 124 and a shallow well 126. In accordance with the present disclosure, the first resin layer 104 can permit passage of light. In accordance with the present disclosure, the second resin layer 106 can block light, for example by absorbing light.

The substrate may be subject to etching, for example dry etching, which may expose a first surface 114, residing in the first resin layer 104, and a second surface 116, residing within the second resin layer 106. The first surface 114 may be parallel to the base support 102 and within the deep well 124. The second surface 116 may be parallel to the base support 102 and within the shallow well 126.

A photoresist 502 may be introduced to the substrate. The photoresist 502 may cover the substrate, including the first surface 114, the second surface 116, and interstitial regions of the substrate (i.e., regions between each of the plurality of multi-level depressions 122).

The substrate may be exposed to light from the backside of the of the base support 102 (i.e., the side of the base support 102 opposite the imprint layer 120). The first resin layer 104 can allow passage of light to the deep well 124, but the second resin layer 106 can block light, preventing light from reaching the shallow well 126 and interstitial regions of the substrate. Exposure to light can solubilize the photoresist 502 residing within the deep well 124 of each of the plurality of multi-level depressions 122. In some embodiments, the photoresist 502 is a positive photoresist. Solubilized photoresist may be removed, thereby exposing the first surface 114.

A first functionalized molecule 108 may be deposited over the substrate to cover at least a portion of the first surface 114.

The photoresist 502 may be removed from the substrate. The photoresist 502 may be removed by a photoresist stripping process.

The second resin layer 106 may be removed from the substrate. The substrate may be subjected to etching to remove second resin layer 106. In some embodiments, the second resin layer 106 can be removed via wet etching. Removal of the second resin layer 106 leaves the substrate having the first functionalized molecule 108 within the nanowell 130.

### EXAMPLES

Some aspects of the embodiments discussed above are disclosed in further detail in the following examples, which are not in any way intended to limit the scope of the present disclosure. Those in the art will appreciate that many other embodiments also fall within the scope of the compositions, kits, and methods of the present application, as is described herein above and in the claims.

### Resins Including Titanium Oxide Nanoparticles

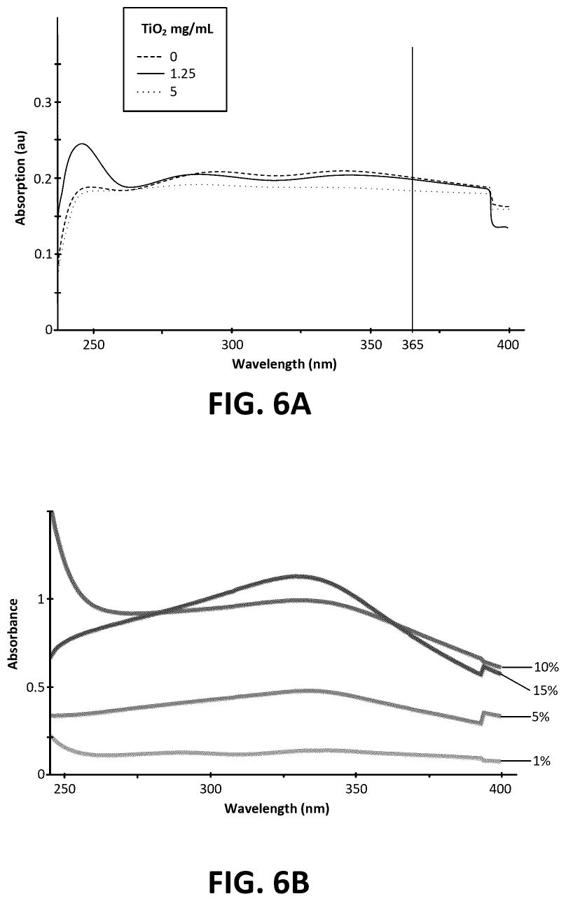

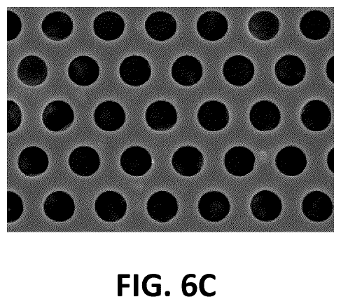

FIG. 6A plots absorption as a function of light wavelength for a resin including 5 nm titanium oxide (TiO₂) nanoparticles at two different concentrations (1.25 mg/mL and 5 mg/mL), alongside a control resin not including TiO₂ nanoparticles (0 mg/mL). The resin used was an organic acrylate resin.

FIG. 6B plots absorbance as a function of light wavelength for a resin including 100 nm TiO₂ nanoparticles at four different concentrations (1%, 5%, 10%, and 15% TiO₂by weight). The resin used was an organic acrylate resin. Additionally, a solvent ratio of 1:4 ethanol/PGMEA and 20 weight % of surfactant with respect to the TiO₂ nanoparticles was used. Table 2 below shows formulation ratios for various constituents of the acrylate resin.

TABLE 2
Acrylate Resin formulation

| | Stock | | Solids |
|---|---|---|---|
| Chemical | concentration | Solvent | composition |
| PE3A | 30.00% | PGMEA | 80-97% |
| DPBAPO | 6.10% | PGMEA | 1.6-1.9% |
| TiO₂ (5, 20, 100 | — | — | 1-15% |
| nm NPs) | | | |
| DISPERBYK-110 | 52.0% | methoxypropylacetate/ | 0.2-3% |
| (surfactant) | | alkylbenzenes 1/1 | |
| PGMEA | — | — | — |

FIG. 6C is a SEM image of a nanoimprinted 10% TiO₂ organic acrylate resin. To create the imprinted surface, a blank wafer was subjected to a 30 second air plasma ash. Acrylate silane primer was spin-coated at 2,000 rpm for 20 seconds. The substrate was prime soft-baked at 130° C. for 2 minutes. The organic acrylate resin was spin coated onto the substrate at 3,000 rpm for 60 seconds. The layer was contacted with a working stamp and allowed to UV cure for 2 seconds, at 365 nm wavelength and 100% power. The ethanol:PGMEA solvent ratio of the resin was 1:4 and 20 weight % with respect to the TiO₂ nanoparticles was used.

### Resins Including Bisoctrizole

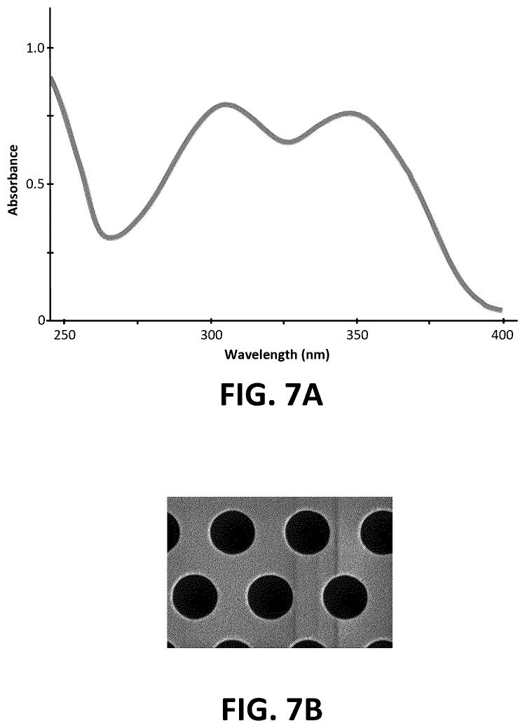

FIG. 7A plots absorption of a resin including bisoctrizole. The resin is an organic acrylate resin including 5% bisoctrizole by mass, 120% surfactant, and 90% chloroform. A solvent ratio of 9:1 chloroform/PGMEA and 120% surfactant with respect to the weight of bisoctrizole was used.

FIG. 7B is an SEM of an imprinted resin containing 5 weight % bisoctrizole, in accordance with the formulation of the resin created for FIG. 7A. To create the imprinted surface, a blank wafer was subjected to a 30 second air plasma ash. Acrylate silane primer was spin-coated at 2,000 rpm for 20 seconds. The substrate was prime soft-baked at 130° C. for 2 minutes. The organic acrylate resin was spin coated onto the substrate at 3,000 rpm for 60 seconds. The layer was contacted with a working stamp and allowed to UV cure for 2 seconds, at 365 nm wavelength and 100% power.

### Resins Including Avobenzone

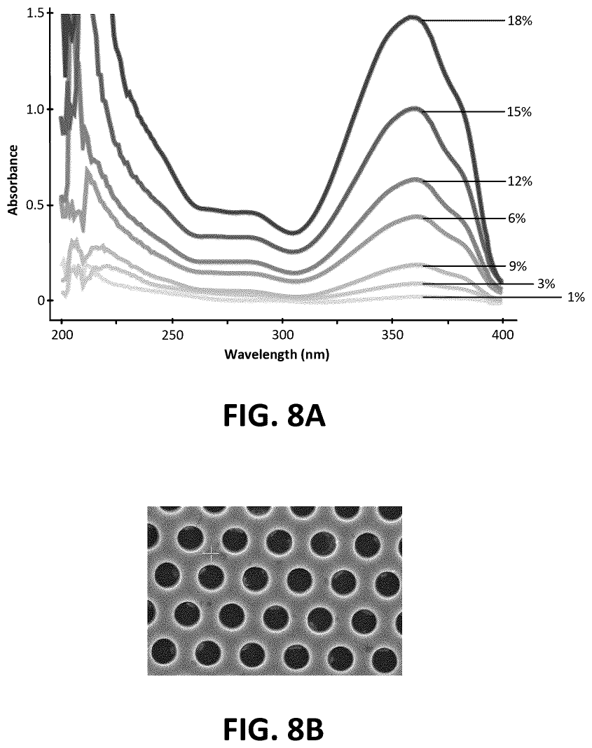

FIG. 8A plots absorbance of resins including avobenzone. The resin is an organic acrylate resin including from 1% to 18% avobenzone by weight. Surfactant used for each resin was 120% of weigh with respect to the avobenzone included.

FIG. 8B is an SEM of a nanoimprinted resin containing 18 weight % avobenzene, in accordance with the formulation of the resin created for FIG. 7A. To create the imprinted surface, a blank wafer was subjected to a 30 second air plasma ash. Acrylate silane primer was spin-coated at 2,000 rpm for 20 seconds. The substrate was prime soft-baked at 130° C. for 2 minutes. The organic acrylate resin was spin coated onto the substrate at 3,000 rpm for 60 seconds. The layer was contacted with a working stamp and allowed to UV cure for 2 seconds, at 365 nm wavelength and 100% power.

### Resins Including Zinc Acrylate

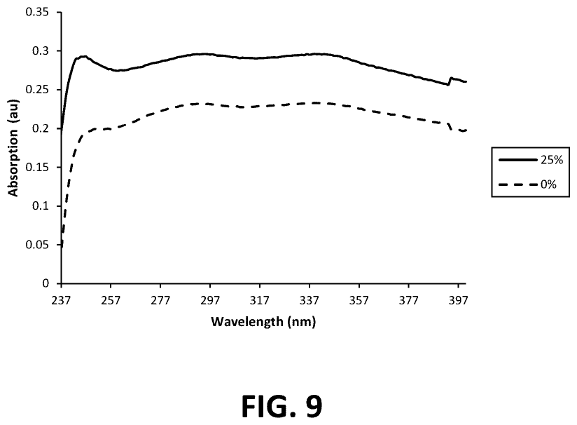

FIG. 9 plots absorption of a resin including a zinc acrylate against a control. The zinc acrylate was included at 25 weight %. The resin used was an organic acrylate resin.

1. A patterned substrate, comprising:
a base support; and
an imprint layer comprising
a first resin layer positioned over the base support, the first resin layer configured to allow passage of light;
a second resin layer positioned over the first resin layer, the second resin layer configured as a photomask for blocking passage of light;
a plurality of multi-level depressions, each multi-level depression comprising a deep well having a first inner well surface and a first surrounding surface, and a shallow well having a second inner well surface and a second surrounding surface, wherein the deep well and the shallow well are defined by a step portion, each of the first inner well surface and the second inner well surface is parallel to the base support, the first inner well surface resides within the first resin layer, and the second inner well surface resides within the second resin layer.

2. A patterned substrate, comprising:
a base support; and
an imprint layer comprising
a first resin layer positioned over the base support, the first resin layer configured to allow passage of light;
a second resin layer positioned over the first resin layer, the second resin layer configured as a photomask to block passage of light;
a third resin layer positioned over the second resin layer, the third resin layer configured to allow passage of light;
a plurality of multi-level depressions, each depression comprising a deep well having a first inner well surface and a first surrounding surface, and a shallow well having a second inner well surface and a second surrounding surface, wherein the deep well and the shallow well are defined by a step portion, each of the first inner well surface and the second inner well surface is parallel to the base support, the first surface resides within the first resin layer, and the second inner well surface resides within either the second resin layer or third resin layer.

3. (canceled)

4. (canceled)

5. The patterned substrate of claim 1, wherein the patterned substrate is configured for exposing a photoresist positioned within the deep well of the depression over the first inner well surface to a light passing through the base support and the first resin layer.

6. The patterned substrate of claim 1, wherein the first resin layer is configured to allow passage of UV light, and wherein the second resin layer is a photomask for UV light comprising one or more UV light-absorbing agents.

7. The patterned substrate of claim 1, wherein the patterned substrate does not include a metallic photomask.

8. The patterned substrate of claim 1, wherein the second resin layer is dry etchable and/or wet etchable.

9. (canceled)

10. (canceled)

11. The patterned substrate of claim 1, wherein the first resin layer is not wet etchable, and wherein the first resin layer is dry etchable.

12. (canceled)

13. The patterned substrate of claim 1, wherein the second resin layer comprises an epoxy resin.

14. The patterned substrate of claim 13, wherein the epoxy resin comprises at least one of 3,4-epoxycyclohexylmethyl 3,4-epoxycyclohexanecarboxylate (ECHC), trimethylolpropane triglycidyl ether (TTE), BIS(4-methylphenyl)iodonium hexafluorophosphate (IPF), tris (4-((4-acetylphenyl)thio)phenyl)-sulfonium tetrakis(perfluoro-phenyl) borate (PAG290), or diphenyl (2,4,6-trimethylbenzoyl)phosphine oxide (DPBAPO).

15. The patterned substrate of claim 1, wherein the second resin layer comprises an acrylate resin.

16. The patterned substrate of claim 15, wherein the acrylate resin comprises at least one of pentaerythritol triacrylate (PE3A) or diphenyl (2,4,6-trimethylbenzoyl)phosphine oxide (DPBAPO).

17. (canceled)

18. (canceled)

19. (canceled)

20. The patterned substrate of claim 6, wherein the one or more UV-absorbing agents are selected from the group consisting of ZnO nanoparticles, TiO₂ nanoparticles, ZrO₂ nanoparticles, Zn-conjugated acrylate, Ti-conjugated acrylate, Zr-conjugated acrylate, Zn-conjugated epoxy, Ti-conjugated epoxy, Zr-conjugated epoxy, carbon black, photoinitiator (PI), photoacid generator (PAG), quencher dye, poly(pyrrole), poly(thiophene), poly(phenylene), dithiomaleimide and dibromomaleimide, avobenzone, bisoctrizole, meradimate, dioxybenzone, oxybenzone, drometrizole, 4-methacryloxy-2-hydroxybenzophenone, 2,2-dihydroxy, 4-methoxybenzophenone, methyl-2-cyan-3-(4-hydroxyphenyl)acrylate, (E)-ethyl 2-(3-ethoxy-4-hydroxybenzylidene)-3-oxobutanoate, ethyl-2-cyano-3-(4-hydroxy-3-methoxy phenyl)acrylate, and dimethyl 2-(4-hydroxybenzylidene)malonate, and combinations thereof.

21. The patterned substrate of claim 20, wherein the second resin layer comprises from about 1% to about 15% TiO₂ nanoparticles by weight.

22. (canceled)

23. (canceled)

24. The patterned substrate of claim 20, wherein the second resin layer comprises from about 10% to about 40% Zn-conjugated acrylate by weight.

25. The patterned substrate of claim 20, wherein the second resin layer comprises from about 1% to about 15% bisoctrizole by weight.

26. The patterned substrate of claim 20, wherein the second resin layer comprises from about 0.5% to about 30% avobenzone by weight.

27. The patterned substrate of claim 1, wherein a thickness of the second resin layer defined between the first resin layer and a top surface of the second resin layer is between about 20 nm and about 1 m.

28. A method for functionalizing a surface of a patterned substrate, comprising:
depositing a first functionalized molecule on the patterned substrate of claim 1, wherein the first functionalized molecule covers a top surface of the second resin layer and the surfaces of at least a portion of the deep wells and the shallow wells of the plurality multi-level depressions;
introducing a photoresist into the multi-level depressions of the substrate;
exposing the substrate to light from a backside of the base support opposite to the imprint layer such that only the photoresist residing within the deep wells of the multi-level depressions are cured, and the photoresist residing within the shallow wells of the multi-level depressions remains unexposed to light and uncured; and
removing the uncured photoresist from the substrate.

29. A method for functionalizing a surface of a patterned substrate, comprising:
depositing a first functionalized molecule on the patterned substrate of claim 2, wherein the first functionalized molecule covers a top surface of the third resin layer and the surfaces of at least a portion of the deep wells and the shallow wells of the plurality multi-level depressions;
introducing a photoresist into the multi-level depressions of the substrate;
exposing the substrate to light from a backside of the base support opposite to the imprint layer such that only the photoresist residing within the deep wells of the multi-level depressions are cured, and the photoresist residing within the shallow wells of the multi-level depressions remains unexposed to light and uncured; and
removing the uncured photoresist from the substrate.

30. The method of claim 28, further comprising:
etching the imprint layer to remove the second resin layer and to form a third inner well surface in each of the shallow wells, wherein the third inner well surface resides within the first resin layer, and the third inner well surface is parallel to the base support;
depositing a second functionalized molecule on the first resin layer to cover at least a portion of the third inner well surfaces and the cured photoresist; and
removing the cured photoresist from the substrate;
wherein the first functionalized molecule remains on at least a portion of the first inner well surfaces and the second functionalized molecule remains on at least a portion of the third inner well surfaces; and
wherein the etching removes the step portion between each deep well and shallow well.

31. (canceled)

32. (canceled)

33. (canceled)

34. (canceled)

35. (canceled)

36. A method for functionalizing a surface of a patterned substrate comprising a plurality of multi-level depressions, the method comprising:
introducing a photoresist into the multi-level depressions of the patterned substrate according to claim 1;
exposing the substrate to light from a backside of the base support opposite to the imprint layer such that only the photoresist residing within the deep wells of the multi-level depressions is cured, and the photoresist residing within the shallow wells of the multi-level depressions remains unexposed to light and uncured;
removing the uncured photoresist from the substrate;
etching the imprint layer to remove the second resin layer and to form a third inner well surface in each of the shallow wells, wherein the third inner well surface resides within the first resin layer, and the third inner well surface is parallel to the base support;
depositing a first functionalized molecule on the first resin layer to cover at least a portion of the third inner well surfaces and the cured photoresist;
removing the cured photoresist from the substrate, thereby exposing the first inner well surfaces; and
depositing a second functionalized molecule on the first inner well surfaces.

37. (canceled)

38. (canceled)

39. (canceled)

40. (canceled)

41. A method for functionalizing a surface of a patterned substrate comprising a plurality of multi-level depressions, comprising:
introducing a positive photoresist into the multi-level depressions of the patterned substrate according to claim 1;
exposing the substrate to light from a backside of the base support opposite to the imprint layer such that only the photoresist residing within the deep wells of the multi-level depressions is exposed to light, and the photoresist residing within the shallow wells of the multi-level depressions remains unexposed to light;
removing light exposed photoresist from the substrate;
depositing a functionalized molecule on the imprint layer of the substrate to cover at least a portion of the first inner well surfaces;
removing the second resin layer and remaining unexposed positive photoresist by etching.

42.-64. (canceled)
